(19) United States
(12) Patent Application Publication
(10) Pub. No.: US 2014/0124907 A1
(43) Pub. Date: May 8, 2014

(54) SEMICONDUCTOR PACKAGES

(71) Applicant: Soo-Jeoung Park, Hwaseong-si (KR)

(72) Inventor: Soo-Jeoung Park, Hwaseong-si (KR)

(21) Appl. No.: 13/957,955

(22) Filed: Aug. 2, 2013

(30) Foreign Application Priority Data
Nov. 5, 2012 (KR) 10-2012-0124398

(51) Int. Cl. H01L 23/552

(52) U.S. Cl. CPC H01L 23/552
USPC 257/659

(57) ABSTRACT

A semiconductor package includes a mounting substrate having a chip-mounting region and a peripheral region, a first semiconductor chip mounted on the chip-mounting region of the mounting substrate, a first molding member on the mounting substrate to cover at least a portion of the first semiconductor chip, a plurality of first conductive connection members penetrating at least a portion of the first molding member, the first conductive connection members electrically connected to a plurality of ground connection pads provided on the peripheral region of the mounting substrate, respectively, and an electromagnetic interference (EMI) shield member covering the first semiconductor chip and including a graphite layer electrically connected to the first conductive connection members.

### PRIORITY STATEMENT

This application claims priority under 35 U.S.C. §119 to Korean Patent Application No. 10-2012-0124398, filed on Nov. 5, 2012 in the Korean Intellectual Property Office (KIPO), the contents of which are herein incorporated by reference in their entirety.

### BACKGROUND

1. Field

Exemplary embodiments in accordance with principles of inventive concepts relate to a semiconductor package and a method of manufacturing a semiconductor package. More particularly, exemplary embodiments in accordance with principles of inventive concepts relate to a semiconductor package including a semiconductor chip and a method of manufacturing the semiconductor package.

2. Description of the Related Art

Electromagnetic waves emitted from a semiconductor package may generate noise and interference with devices within range of the emissions and may cause those devices to malfunction or otherwise create errors. Electromagnetic interference (EMI) shields may be installed to prevent such interference. However, conventional shielding, such as the use of a radiation plate that covers at least one surface of an electronic device, may add to the thickness of the final semiconductor package and degrade or limit the EMI shielding performance.

### SUMMARY

Exemplary embodiments in accordance with principles of inventive concepts include a semiconductor package that includes a mounting substrate having a chip-mounting region and a peripheral region, a first semiconductor chip mounted on the chip-mounting region of the mounting substrate, a first molding member on the mounting substrate to cover at least a portion of the first semiconductor chip, a plurality of first conductive connection members penetrating at least a portion of the first molding member, the first conductive connection members electrically connected to a plurality of ground connection pads provided on the peripheral region of the mounting substrate, respectively, and an electromagnetic interference (EMI) shield member including a graphite layer covering the first semiconductor chip and electrically connected to the first conductive connection members.

Exemplary embodiments in accordance with principles of inventive concepts include a semiconductor package wherein the first molding member leaves exposed an upper surface of the first semiconductor chip.

Exemplary embodiments in accordance with principles of inventive concepts include a semiconductor package wherein the EMI shield member makes electrical contact with the exposed upper surface of the first semiconductor chip.

Exemplary embodiments in accordance with principles of inventive concepts include a semiconductor package wherein the first semiconductor chip is electrically connected to the mounting substrate by a plurality of bumps.

Exemplary embodiments in accordance with principles of inventive concepts include a semiconductor package, wherein an EMI shield member makes electrical contact with the first conductive connection members.

Exemplary embodiments in accordance with principles of inventive concepts include a semiconductor package wherein the first conductive connection member includes a solder ball disposed on the ground connection pad, and an end portion of the solder ball is exposed by the first molding member.

Exemplary embodiments in accordance with principles of inventive concepts include a semiconductor package wherein the first conductive connection member comprises a conductive material, through-holes are formed in the first molding member to expose the ground connection pads, and the conductive material fills the through-holes.

Exemplary embodiments in accordance with principles of inventive concepts include a semiconductor package wherein an EMI shield member includes a support layer supporting the graphite layer; and a conductive adhesive layer on the graphite layer.

Exemplary embodiments in accordance with principles of inventive concepts include a semiconductor package wherein an EMI shield member covers at least a portion of an outer side surface of the mounting substrate.

Exemplary embodiments in accordance with principles of inventive concepts include a semiconductor package including a second semiconductor chip stacked on the first semiconductor chip, and wherein the second semiconductor chip is electrically connected to the first semiconductor chip by a plurality of through-electrodes that penetrate the first semiconductor chip.

Exemplary embodiments in accordance with principles of inventive concepts include a semiconductor package including a redistribution wiring substrate stacked on the first molding member and electrically connected to the first conductive connection members, a second semiconductor chip mounted on a chip-mounting region of the redistribution wiring substrate, a second molding member on the redistribution wiring substrate to cover at least of a portion of the second semiconductor chip, and a plurality of second conductive connection members penetrating at least a portion of the second molding member, the second conductive connection members electrically connected to a plurality of ground connection pads provided on a peripheral region of the redistribution substrate, respectively.

Exemplary embodiments in accordance with principles of inventive concepts include a semiconductor package wherein the second molding member exposes an upper surface of the second semiconductor chip.

Exemplary embodiments in accordance with principles of inventive concepts include a semiconductor package wherein the EMI shield member makes electrical contact with the exposed upper surface of the second semiconductor chip.

Exemplary embodiments in accordance with principles of inventive concepts include a semiconductor package wherein the EMI shield member makes electrical contact with the first conductive connection members.

Exemplary embodiments in accordance with principles of inventive concepts include a semiconductor package, that includes a mounting substrate, a first semiconductor chip mounted on the mounting substrate, a first molding member on the mounting substrate that leaves exposed an upper surface of the first semiconductor chip, and an electromagnetic interference (EMI) shield member including a graphite layer on the first molding member and covering the first semiconductor chip.

Exemplary embodiments in accordance with principles of inventive concepts include a semiconductor package wherein the EMI shield member makes electrical contact with the exposed upper surface of the first semiconductor chip.

Exemplary embodiments in accordance with principles of inventive concepts include a semiconductor package wherein the EMI shield member includes a support layer supporting the graphite layer and a conductive adhesive layer on the graphite layer.

Exemplary embodiments in accordance with principles of inventive concepts include a semiconductor package including a heat dissipation plate on the EMI shield member.

Exemplary embodiments in accordance with principles of inventive concepts include a semiconductor package wherein the EMI shield member further comprises first and second adhesive layers on upper and lower surfaces of the graphite layer.

Exemplary embodiments in accordance with principles of inventive concepts include a semiconductor package including a plurality of first conductive connection members penetrating at least a portion of the first molding member, the first conductive connection members electrically connected to a plurality of ground connection pads provided on a peripheral region of the mounting substrate, respectively, and wherein the graphite layer of the EMI shield member is electrically connected to the first conductive connection members.

Exemplary embodiments in accordance with principles of inventive concepts include a method of manufacturing a semiconductor package, including preparing a mounting substrate having a chip-mounting region and a peripheral region, disposing a first semiconductor chip on the chip-mounting region of the mounting substrate, forming a first molding member covering at least a portion of the first semiconductor chip on the mounting substrate and having first conductive connection members, the first conductive connection members penetrating through at least a portion of the first molding member and electrically connected to a plurality of ground connection pads formed on the peripheral region of the mounting substrate, respectively, and disposing an EMI shield member including a graphite layer to cover the first semiconductor chip, the EMI shield member layer electrically connected to the first conductive molding members.

Exemplary embodiments in accordance with principles of inventive concepts include a method wherein forming the first molding member comprises: arranging solder balls on the ground connection pads formed on the peripheral region of the mounting substrate, respectively; and forming the first molding member to cover at least the portion of the first semiconductor chip on the mounting substrate and to expose end portions of the solder balls.

Exemplary embodiments in accordance with principles of inventive concepts include a method wherein forming the first molding member comprises: forming a first preliminary molding member to cover at least the portion of the first semiconductor chip on the mounting substrate; forming through-holes in the first preliminary molding member to expose the ground connection pads formed on the peripheral region of the mounting substrate; and filling the through-holes with a conductive material.

Exemplary embodiments in accordance with principles of inventive concepts include a method wherein the first molding member is formed to leave exposed an upper surface of the first semiconductor chip.

Exemplary embodiments in accordance with principles of inventive concepts include a method wherein the EMI shield member makes contact with the exposed upper surface of the first semiconductor chip.

Exemplary embodiments in accordance with principles of inventive concepts include a method wherein disposing the first semiconductor chip on the chip-mounting region of the mounting substrate comprises electrically connecting the first semiconductor chip to the mounting substrate using a plurality of bumps.

Exemplary embodiments in accordance with principles of inventive concepts include a method wherein forming the EMI shield member includes forming the EMI shield member to make electrical contact with the first conductive connection members.

Exemplary embodiments in accordance with principles of inventive concepts include a method wherein forming the EMI shield member further comprises: forming a support layer supporting the graphite layer; and forming a conductive adhesive layer on the graphite layer.

Exemplary embodiments in accordance with principles of inventive concepts include a method comprising stacking a second semiconductor chip on the first semiconductor chip, and wherein the second semiconductor chip is electrically connected to the first semiconductor chip by a plurality of through-electrodes that penetrate the first semiconductor chip.

Exemplary embodiments in accordance with principles of inventive concepts include a method comprising: stacking a redistribution wiring substrate on the first molding member to be electrically connected to the first conductive connection members; mounting a second semiconductor chip on a chip-mounting region of the redistribution wiring substrate; and forming a second molding member on the redistribution wiring substrate to cover at least of a portion of the second semiconductor chip, the second molding member having a plurality of second conductive connection members penetrating at least a portion of the first molding member, the second conductive connection members electrically connected to a plurality of ground connection pads provided on a peripheral region of the redistribution wiring substrate, respectively.

Exemplary embodiments in accordance with principles of inventive concepts include a method wherein the second molding member is formed to expose an upper surface of the second semiconductor chip.

Exemplary embodiments in accordance with principles of inventive concepts include a method of wherein the EMI shield member is formed to make contact with the exposed upper surface of the second semiconductor chip.

Exemplary embodiments in accordance with principles of inventive concepts include a method wherein the EMI shield member is formed to make electrical contact with the second conductive connection members.

Exemplary embodiments in accordance with principles of inventive concepts include an electronic memory, comprising: a mounting substrate having a chip-mounting region and a peripheral region; a first semiconductor memory chip mounted on the chip-mounting region of the mounting substrate; a first molding member on the mounting substrate to cover a portion of the first semiconductor memory chip, leaving the upper surface exposed; a plurality of first conductive connection members penetrating at least a portion of the first molding member, the first conductive connection members electrically connected to a plurality of ground connection pads provided on the peripheral region of the mounting substrate, respectively; a second semiconductor memory chip stacked on the first semiconductor memory chip, wherein the second semiconductor memory chip is electrically connected to the first semiconductor memory chip by a plurality of through-electrodes that penetrate the first semiconductor memory chip; and an electromagnetic interference (EMI) shield member including a graphite layer covering the first semiconductor memory chip, electrically connected to the first conductive connection members and in contact with the exposed upper surface of the first semiconductor memory chip.

Exemplary embodiments in accordance with principles of inventive concepts include a semiconductor memory of wherein the first semiconductor memory chip is electrically connected to the mounting substrate by a plurality of bumps.

Exemplary embodiments in accordance with principles of inventive concepts include a semiconductor memory wherein the EMI shield member makes electrical contact with the first conductive connection members.

Exemplary embodiments in accordance with principles of inventive concepts include a semiconductor memory wherein the first conductive connection member includes a solder ball disposed on the ground connection pad, and an end portion of the solder ball is exposed by the first molding member.

Exemplary embodiments in accordance with principles of inventive concepts include a semiconductor memory wherein the first conductive connection member comprises a conductive material, through-holes are formed in the first molding member to expose the ground connection pads, and the conductive material fills the through-holes.

Exemplary embodiments in accordance with principles of inventive concepts include a semiconductor memory wherein the EMI shield member comprises: a support layer supporting the graphite layer; and a conductive adhesive layer on the graphite layer, wherein the EMI shield member covers at least a portion of an outer surface of the mounting substrate.

Exemplary embodiments in accordance with principles of inventive concepts include a semiconductor memory comprising: a redistribution wiring substrate stacked on the first molding member and electrically connected to the first conductive connection members; wherein the second semiconductor memory chip is mounted on a chip-mounting region of the redistribution wiring substrate; a second molding member on the redistribution wiring substrate to cover a portion of the second semiconductor chip, leaving exposed an upper surface of the second semiconductor memory chip; and a plurality of second conductive connection members penetrating at least a portion of the second molding member, the second conductive connection members electrically connected to a plurality of ground connection pads provided on a peripheral region of the redistribution substrate, respectively.

Exemplary embodiments in accordance with principles of inventive concepts include a semiconductor memory wherein the EMI shield member makes electrical contact with the exposed upper surface of the second semiconductor chip.

Exemplary embodiments in accordance with principles of inventive concepts include an electronic memory system including a semiconductor memory comprising: a mounting substrate having a chip-mounting region and a peripheral region; a first semiconductor memory chip mounted on the chip-mounting region of the mounting substrate; a first molding member on the mounting substrate to cover a portion of the first semiconductor memory chip, leaving the upper surface exposed; a plurality of first conductive connection members penetrating at least a portion of the first molding member, the first conductive connection members electrically connected to a plurality of ground connection pads provided on the peripheral region of the mounting substrate, respectively; a second semiconductor memory chip stacked on the first semiconductor memory chip, wherein the second semiconductor memory chip is electrically connected to the first semiconductor memory chip by a plurality of through-electrodes that penetrate the first semiconductor memory chip; and an electromagnetic interference (EMI) shield member including a graphite layer covering the first semiconductor memory chip, electrically connected to the first conductive connection members and in contact with the exposed upper surface of the first semiconductor memory chip.

Exemplary embodiments in accordance with principles of inventive concepts include an electronic system that includes a memory system including a semiconductor memory comprising: a mounting substrate having a chip-mounting region and a peripheral region; a first semiconductor memory chip mounted on the chip-mounting region of the mounting substrate; a first molding member on the mounting substrate to cover a portion of the first semiconductor memory chip, leaving the upper surface exposed; a plurality of first conductive connection members penetrating at least a portion of the first molding member, the first conductive connection members electrically connected to a plurality of ground connection pads provided on the peripheral region of the mounting substrate, respectively; a second semiconductor memory chip stacked on the first semiconductor memory chip, wherein the second semiconductor memory chip is electrically connected to the first semiconductor memory chip by a plurality of through-electrodes that penetrate the first semiconductor memory chip; and an electromagnetic interference (EMI) shield member including a graphite layer covering the first semiconductor memory chip, electrically connected to the first conductive connection members and in contact with the exposed upper surface of the first semiconductor memory chip.

Exemplary embodiments in accordance with principles of inventive concepts include a portable electronic device that includes a semiconductor memory comprising: a mounting substrate having a chip-mounting region and a peripheral region; a first semiconductor memory chip mounted on the chip-mounting region of the mounting substrate; a first molding member on the mounting substrate to cover a portion of the first semiconductor memory chip, leaving the upper surface exposed; a plurality of first conductive connection members penetrating at least a portion of the first molding member, the first conductive connection members electrically connected to a plurality of ground connection pads provided on the peripheral region of the mounting substrate, respectively; a second semiconductor memory chip stacked on the first semiconductor memory chip, wherein the second semiconductor memory chip is electrically connected to the first semiconductor memory chip by a plurality of through-electrodes that penetrate the first semiconductor memory chip; and an electromagnetic interference (EMI) shield member including a graphite layer covering the first semiconductor memory chip, electrically connected to the first conductive connection members and in contact with the exposed upper surface of the first semiconductor memory chip.

Exemplary embodiments include a wireless electronic device that includes a semiconductor memory comprising: a mounting substrate having a chip-mounting region and a peripheral region; a first semiconductor memory chip mounted on the chip-mounting region of the mounting substrate; a first molding member on the mounting substrate to cover a portion of the first semiconductor memory chip, leaving the upper surface exposed; a plurality of first conductive connection members penetrating at least a portion of the first molding member, the first conductive connection members electrically connected to a plurality of ground connection pads provided on the peripheral region of the mounting substrate, respectively; a second semiconductor memory chip stacked on the first semiconductor memory chip, wherein the second semiconductor memory chip is electrically connected to the first semiconductor memory chip by a plurality of through-electrodes that penetrate the first semiconductor memory chip; and an electromagnetic interference (EMI) shield member including a graphite layer covering the first semiconductor memory chip, electrically connected to the first conductive connection members and in contact with the exposed upper surface of the first semiconductor memory chip. According to example embodiments, a semiconductor package includes a mounting substrate having a chip-mounting region and a peripheral region, a first semiconductor chip mounted on the chip-mounting region of the mounting substrate, a first molding member on the mounting substrate to cover at least a portion of the first semiconductor chip, a plurality of first conductive connection members penetrating at least a portion of the first molding member, the first conductive connection members electrically connected to a plurality of ground connection pads provided on the peripheral region of the mounting substrate, respectively, and an electromagnetic interference (EMI) shield member covering the first semiconductor chip and including a graphite layer electrically connected to the first conductive connection members.

In example embodiments, the first molding member may expose an upper surface of the first semiconductor chip.

In example embodiments, the EMI shield member may make contact with the exposed upper surface of the first semiconductor chip.

In example embodiments, the first semiconductor chip may be electrically connected to the mounting substrate by a plurality of bumps.

In example embodiments, the EMI shield member may make contact with the first conductive connection members.

In example embodiments, the first conductive connection member may include a solder ball, the solder ball may be disposed on the ground connection pad, and an end portion of the solder ball may be exposed by the first molding member.

In example embodiments, the first conductive connection member may include a conductive material, through-holes may be formed in the first molding member to expose the ground connection pads, and the conductive material may fill up the through-holes.

In example embodiments, the EMI shield member may further include a support layer supporting the graphite layer, and a conductive adhesive layer on the graphite layer.

In example embodiments, the EMI shield member may cover at least a portion of an outer side surface of the mounting substrate.

In example embodiments, the semiconductor package may further include a second semiconductor chip stacked on the first semiconductor chip, and the second semiconductor chip may be electrically connected to the first semiconductor chip by a plurality of through-electrodes that penetrate the first semiconductor chip.

In example embodiments, the semiconductor package may further include a redistribution wiring substrate stacked on the first molding member and electrically connected to the first conductive connection members, a second semiconductor chip mounted on a chip-mounting region of the redistribution wiring substrate, a second molding member on the redistribution wiring substrate to cover at least of a portion of the second semiconductor chip, and a plurality of second conductive connection members penetrating at least a portion of the second molding member, the second conductive connection members electrically connected to a plurality of ground connection pads provided on a peripheral region of the redistribution substrate, respectively.

In example embodiments, the second molding member may expose an upper surface of the second semiconductor chip.

In example embodiments, the EMI shield member may make contact with the exposed upper surface of the second semiconductor chip.

In example embodiments, the EMI shield member may make contact with the first conductive connection members.

According to example embodiments, a semiconductor package includes a mounting substrate, a first semiconductor chip mounted on the mounting substrate, a first molding member on the mounting substrate to expose an upper surface of the first semiconductor chip, and an electromagnetic interference (EMI) shield member on the first molding member and including a graphite layer covering the first semiconductor chip.

In example embodiments, the EMI shield member may make contact with the exposed upper surface of the first semiconductor chip.

In example embodiments, the EMI shield member may further include a support layer supporting the graphite layer, and a conductive adhesive layer on the graphite layer.

In example embodiments, the semiconductor package may further include a heat dissipation plate on the EMI shield member.

In example embodiments, the EMI shield member may further include first and second adhesive layers on upper and lower surfaces of the graphite layer.

In example embodiments, the semiconductor package may further include a plurality of first conductive connection members penetrating at least a portion of the first molding member, the first conductive connection members electrically connected to a plurality of ground connection pads provided on a peripheral region of the mounting substrate, respectively, and the graphite layer of the EMI shield member may be electrically connected to the first conductive connection members.

According to example embodiments, in a method of manufacturing a semiconductor package, a mounting substrate having a chip-mounting region and a peripheral region is prepared. A first semiconductor chip is disposed on the chip-mounting region of the mounting substrate. A first molding member is formed to cover at least a portion of the first semiconductor chip on the mounting substrate and to have first conductive connection members, the first conductive connection members penetrating through at least a portion of the first molding member and electrically connected to a plurality of ground connection pads formed on the peripheral region of the mounting substrate, respectively. An EMI shield member is disposed to cover the first semiconductor chip, the EMI shield member including a graphite layer electrically connected to the first conductive molding members.

In example embodiments, forming the first molding member may include arranging solder balls on the ground connection pads formed on the peripheral region of the mounting substrate, respectively, and forming the first molding member to cover at least the portion of the first semiconductor chip on the mounting substrate and to expose end portions of the solder balls.

In example embodiments, forming the first molding member may include forming a first preliminary molding member to cover at least the portion of the first semiconductor chip on the mounting substrate, forming through-holes in the first preliminary molding member to expose the ground connection pads formed on the peripheral region of the mounting substrate, and filling up the through-holes with a conductive material.

In example embodiments, the first molding member may be formed to expose an upper surface of the first semiconductor chip.

In example embodiments, the EMI shield member may make contact with the exposed upper surface of the first semiconductor chip.

In example embodiments, disposing the first semiconductor chip on the chip-mounting region of the mounting substrate may include electrically connecting the first semiconductor chip to the mounting substrate by a plurality of bumps.

In example embodiments, the EMI shield member may make contact with the first conductive connection members.

In example embodiments, the EMI shield member may further include a support layer supporting the graphite layer, and a conductive adhesive layer on the graphite layer.

In example embodiments, the method may further include stacking a second semiconductor chip on the first semiconductor chip, and the second semiconductor chip may be electrically connected to the first semiconductor chip by a plurality of through-electrodes that penetrate the first semiconductor chip.

In example embodiments, the method may further include stacking a redistribution wiring substrate on the first molding member to be electrically connected to the first conductive connection members, mounting a second semiconductor chip on a chip-mounting region of the redistribution wiring substrate, and forming a second molding member on the redistribution wiring substrate to cover at least of a portion of the second semiconductor chip, the second molding member having a plurality of second conductive connection members penetrating at least a portion of the first molding member, the second conductive connection members electrically connected to a plurality of ground connection pads provided on a peripheral region of the redistribution wiring substrate, respectively.

In example embodiments, the second molding member may be formed to expose an upper surface of the second semiconductor chip.

In example embodiments, the EMI shield member may make contact with the exposed upper surface of the second semiconductor chip.

In example embodiments, the EMI shield member may make contact with the second conductive connection members.

According to example embodiments, a semiconductor package may include an EMI shield member covering a semiconductor chip and having a graphite layer. Ground connection pads may be arranged around the semiconductor chip on an upper surface of a mounting substrate. Conductive connection members may penetrate a molding member to electrically connect the ground connection pads and the graphite layer of the EMI shield member. The graphite layer may include a graphite film having high heat conductivity and an excellent EMI shielding performance.

### BRIEF DESCRIPTION OF THE DRAWINGS

Example embodiments will be more clearly understood from the following detailed description taken in conjunction with the accompanying drawings. FIGS. 1 to 34 represent non-limiting, example embodiments as described herein.

FIG. 1 is a cross-sectional view illustrating an exemplary embodiment of a semiconductor package in accordance with principles of inventive concepts.

FIGS. 2 and 4 to 6 are cross-sectional views illustrating an exemplary method of manufacturing a semiconductor package in accordance with principles of inventive concepts.

FIG. 3 is a plan view of FIG. 2.

FIG. 7 is a graph illustrating an EMI shielding performance of the EMI shield member including the graphite layer in accordance with an example embodiment.

FIG. 8 is a cross-sectional view illustrating an exemplary embodiment of a semiconductor package in accordance with principles of inventive concepts.

FIGS. 9 to 12 are cross-sectional views illustrating an exemplary method of manufacturing the semiconductor package in accordance with principles of inventive concepts.

FIG. 13 is a cross-sectional view illustrating an exemplary embodiment of a semiconductor package in accordance with principles of inventive concepts.

FIG. 14 is a plan view illustrating an EMI shield member of the semiconductor package in FIG. 13.

FIG. 15 is a cross-sectional view illustrating an exemplary embodiment of a semiconductor package in accordance with principles of inventive concepts.

FIG. 16 is a cross-sectional view illustrating an exemplary embodiment of a semiconductor package in accordance with principles of inventive concepts.

FIGS. 17 to 19 are cross-sectional views illustrating an exemplary method of manufacturing a semiconductor package in accordance with principles of inventive concepts.

FIG. 20 is a cross-sectional view illustrating a semiconductor package in accordance with principles of inventive concepts.

FIGS. 21 to 23 are cross-sectional views illustrating an exemplary method of manufacturing a semiconductor package in accordance with principles of inventive concepts.

FIG. 24 is a cross-sectional view illustrating an exemplary embodiment of a semiconductor package in accordance with principles of inventive concepts.

FIGS. 25 and 26 are cross-sectional views illustrating an exemplary method of manufacturing the semiconductor package in accordance with principles of inventive concepts.

FIG. 27 is a cross-sectional view illustrating an exemplary embodiment of a semiconductor package in accordance with principles of inventive concepts.

FIG. 28 is a cross-sectional view illustrating an exemplary embodiment of a semiconductor package in accordance with principles of inventive concepts.

FIG. 29 is a cross-sectional view illustrating an exemplary embodiment of a semiconductor package in accordance with principles of inventive concepts.

FIG. 30 is a plan view illustrating an EMI shield member interposed between first and second packages in FIG. 29.

FIG. 31 is a cross-sectional view illustrating an exemplary embodiment of a semiconductor package in accordance with principles of inventive concepts.

FIG. 32 illustrates another embodiment.

FIG. 33 illustrates still another embodiment.

FIG. 34 illustrates yet another embodiment.

### DETAILED DESCRIPTION OF EXAMPLE EMBODIMENTS

Various exemplary embodiments will be described more fully hereinafter with reference to the accompanying drawings, in which exemplary embodiments are shown. Exemplary embodiments may, however, be embodied in many different forms and should not be construed as limited to exemplary embodiments set forth herein. Rather, these exemplary embodiments are provided so that this disclosure will be thorough, and will convey the scope of exemplary embodiments to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items. The term “or” is used in an inclusive sense unless otherwise indicated.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of exemplary embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular exemplary embodiments only and is not intended to be limiting of exemplary embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations that are schematic illustrations of idealized exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of exemplary embodiments.

Unless otherwise defined, all terms (including technical and scientific terms) used herein have the same meaning as commonly understood by one of ordinary skill in the art to which exemplary embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, exemplary embodiments in accordance with principles of inventive concepts will be explained in detail with reference to the accompanying drawings.

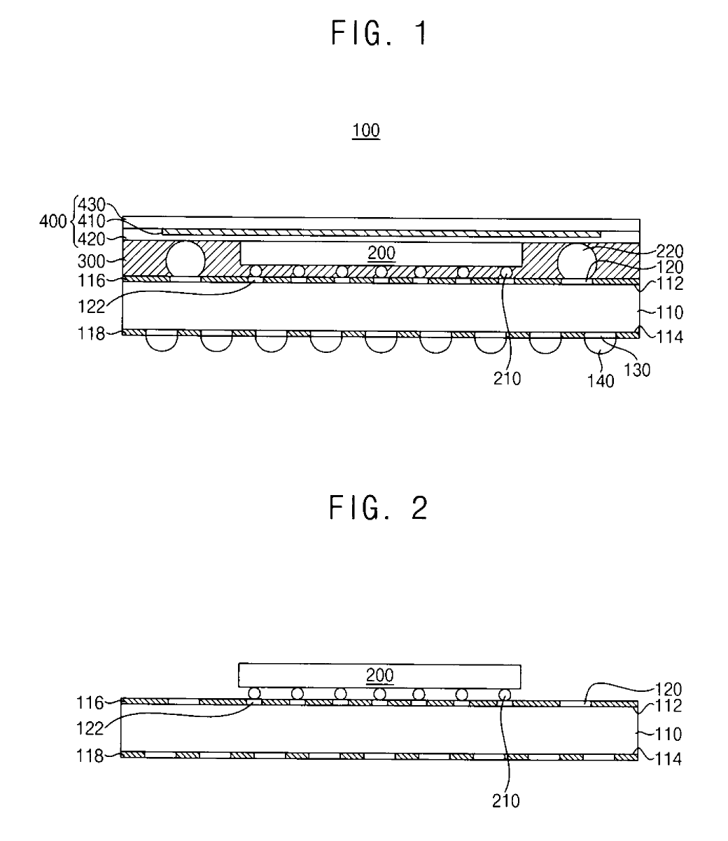

FIG. 1 is a cross-sectional view illustrating a semiconductor package in accordance with exemplary embodiments in accordance with principles of inventive concepts. Semiconductor package 100 may include a mounting substrate 110, a first semiconductor chip 200 mounted on the mounting substrate 110, a first molding member 300 covering at least a portion of the first semiconductor chip 200, first conductive connection members 220 penetrating through at least a portion of the first molding member 300 and spaced apart from the first semiconductor chip 200, and an electromagnetic interference (EMI) shield member 400 covering the first semiconductor chip 200.

In exemplary embodiments in accordance with principles of inventive concepts, the mounting substrate 110 may have an upper surface 112 and a lower surface 114 facing each other. For example, the mounting substrate 110 may be a printed circuit board (PCB). The PCB may be a multi-layered circuit board having various circuits and vias therein.

The mounting substrate 110 may have a chip-mounting region and a peripheral region, for example. The first semiconductor chip 200 may be mounted on the upper surface 112 of the mounting substrate 110. The first semiconductor chip 200 may be disposed in the chip-mounting region of the mounting substrate 110.

First bonding pads 122 for electrical connection with the first semiconductor chip 200 may be formed on the upper surface 112 of the mounting substrate 110. The first bonding pads 122 may be arranged in the chip-mounting region of the mounting substrate 110.

First ground connection pads 120 for electrical connection with the EMI shield member 400 may be formed on the upper surface 112 of the mounting substrate 110. In exemplary embodiments in accordance with principles of inventive concepts, the first ground connection pads 120 may be arranged in the peripheral region around the chip-mounting region.

Outer connection pads 130 for electrical connection with the semiconductor chip 200 may be formed on the lower surface 114 of the mounting substrate 110.

The first bonding pads 122 and the first ground connection pads 120 may be exposed by an insulation layer pattern 116 on the upper surface 112 of the mounting substrate 110, and outer connection pads 130 may be exposed by an insulation layer pattern 118 on the lower surface 114 of the mounting substrate 110. The insulation layer patterns 116 and 118 may include silicon oxide, silicon nitride, or silicon oxynitride, for example.

The first bonding pads 122 and the first ground connection pads 120 may be electrically connected to each other by inner wirings of the mounting substrate 110.

Outer connection members 140 for electrical connection with an external device may be disposed on the outer connection pads 130 of the mounting substrate 110, respectively. For example, the outer connection member 140 may include a solder ball.

In exemplary embodiments in accordance with principles of inventive concepts, the first semiconductor chip 200 may be mounted on the mounting substrate 110 such that an active surface thereof faces the mounting substrate 110. For example, the first semiconductor chip 200 may be mounted on the mounting substrate 110 by a flip-chip bonding method. The first semiconductor chip 200 may be electrically connected to the mounting substrate 110 by bumps 210. The bumps 210 may be solder bumps, for example.

A plurality of the bumps 210 may be arranged on a plurality of the first bonding pads 122, respectively, such that the first semiconductor chip 200 may be adhered to the mounting substrate 110 by the bumps 210. When the first semiconductor chip 200 is adhered to the mounting substrate 110, an adhesive may be underfilled between the first semiconductor chip 200 and the mounting substrate 110 and the adhesive may include an epoxy material to reinforce a gap therebetween.

In an example embodiment, the first conductive connection members 220 may be disposed on the first ground connection pads 120 in the peripheral region of the mounting substrate 110 respectively. For example, the first conductive connection member 220 may include a solder ball.

The first molding member 300 may be formed on the upper surface of the mounting substrate 110 to cover at least a portion of the first semiconductor chip 200, to thereby protect the first semiconductor chip 200.

In exemplary embodiments in accordance with principles of inventive concepts, the first molding member 300 may be formed to expose an upper surface of the first semiconductor chip 200. The first molding member 300 may be formed to expose end portions of the first conductive connection members 220, for example. The end portions of the first conductive connection members 220 may protrude from an upper surface of the first molding member 300. Side surfaces of the first semiconductor chip 200 may be covered by the first molding member 300. In exemplary embodiments in accordance with principles of inventive concepts, the first molding member 300 may have a thickness of 0.18 mm or less.

In exemplary embodiments in accordance with principles of inventive concepts, the EMI shield member 400 may be disposed on the first molding member 300 to cover the first semiconductor chip 200 and may make contact with the upper surface of the first semiconductor chip 200 exposed by the first molding member 300.

In exemplary embodiments in accordance with principles of inventive concepts, the EMI shield member 400 may include a graphite layer 410 electrically connected to the first conductive connection member 220, a support layer 430 supporting the graphite layer 410, and a conductive adhesive layer 420 on the graphite layer 410. The graphite layer 410 may include a graphite tape having high heat conductivity and an excellent EMI shielding performance. The conductive adhesive layer 420 may include a conductive epoxy adhesive. The support layer 430 may include polyimide. The EMI shield member 400 may have a thickness of 0.10 mm or less. In exemplary embodiments in accordance with principles of inventive concepts, the graphite layer 410 may be adhered to the first molding member 300 by the conductive adhesive layer 420 and the conductive adhesive layer 420 may make contact with the graphite layer 410 to electrically connect the graphite layer 410 and the first conductive connection member 220.

Alternatively, the EMI shield member 400 may include a metal layer such as a copper layer. The metal layer may be disposed on the first molding member by the conductive adhesive layer and electrically connected to the first conductive connection member 220.

The first ground connection pads 120 may be electrically connected to the outer connection pads 130 on the lower surface 114 of the mounting substrate 110 by inner wirings, respectively. Accordingly, the EMI shield member 400 may be electrically connected to the outer connection members 140 on the outer connection pads 130 by the first conductive connection members 220.

In exemplary embodiments in accordance with principles of inventive concepts, the semiconductor package 100 may further include a heat dissipation plate such as a heat slug on the EMI shield member 400. The heat dissipation plate may be adhered to the EMI shield member 400 by a conductive adhesive tape, for example.

In exemplary embodiments in accordance with principles of inventive concepts, the first molding member 300 may be provided on the mounting substrate 110 to expose the upper surface of the first semiconductor chip 200, and the EMI shield member 400 including the graphite layer 410 may be provided on the first molding member 300 to make contact with the exposed upper surface of the first semiconductor chip 200.

The first ground connection pads 120 may be arranged in the peripheral region of the mounting substrate 110 away from the first semiconductor chip 200, and the first conductive connection members 220 may be arranged on the first ground connection pads 120 and penetrate the first molding member 300 to electrically connect the first ground connection pad 120 and the graphite layer 410 of the EMI shield member 400. The graphite layer 410 may have high heat conductivity and an excellent EMI shielding performance. Thus, in exemplary embodiments in accordance with principles of inventive concepts, the thickness of the semiconductor package 100 may be reduced while, at the same time, EMI shielding and heat dissipation may be enhanced.

Hereinafter, an exemplary method in accordance with principles of inventive concepts of manufacturing a semiconductor package such as that of FIG. 1 will be described.

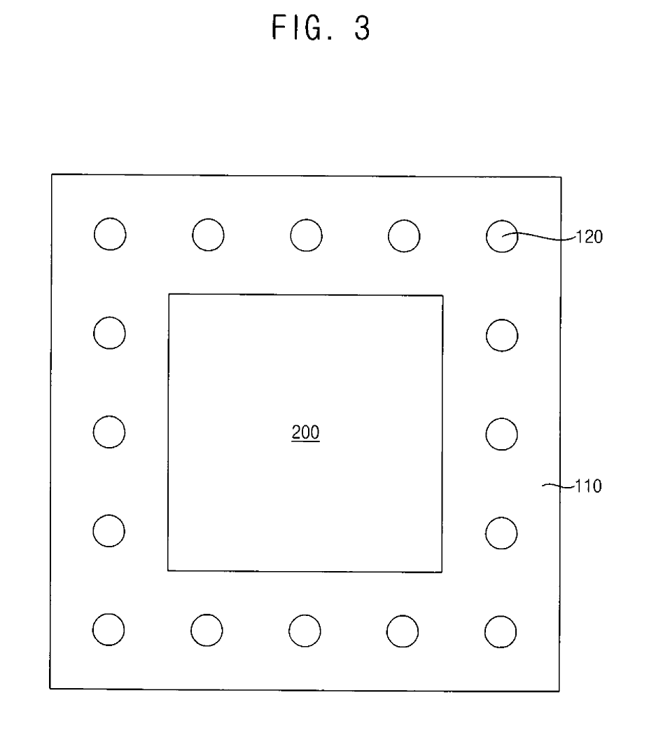

FIGS. 2 and 4 to 6 are cross-sectional views illustrating a method of manufacturing a semiconductor package in accordance with principles of inventive concepts. FIG. 3 is a plan view of FIG. 2. The exemplary method may be used to manufacture the semiconductor package illustrated in FIG. 1, however, its use is not limited thereto.

Referring FIGS. 2 and 3, after a mounting substrate 110 having a chip-mounting region and a peripheral region is prepared, a first semiconductor chip 200 may be mounted on the mounting substrate 110. In exemplary embodiments in accordance with principles of inventive concepts, the mounting substrate 110 may be a PCB having an upper surface 112 and a lower surface 114 facing each other. The PCB may be a multi-layered circuit board having various circuits and vias therein, for example.

The mounting substrate 110 may include a chip-mounting region and a peripheral region. The first semiconductor chip 200 may be mounted on the upper surface 112 of the mounting substrate 110 and may be arranged in the chip-mounting region of the mounting substrate 110.

At least one first ground connection pad 120 and a plurality of first bonding pads 122 may be formed on the upper surface 112 of the mounting substrate 110. A plurality of outer connection pads 130 may be formed on the lower surface 114 of the mounting substrate 110.

In exemplary embodiments in accordance with principles of inventive concepts, a plurality of the first ground connection pads 120 may be arranged in the peripheral region, and a plurality of the first bonding pads 122 may be arranged in the chip-mounting region.

The first ground connection pads 120, the first bonding pads 122 and the outer connection pads 130 may be exposed by insulation layer patterns 116 and 118. The insulation layer patterns 116 and 118 may include silicon oxide, silicon nitride, or silicon oxynitride, for example.

The first ground connection pads 120 and the first bonding pads 122 may be electrically connected to the outer connection pads 130 on the lower surface 114 of the mounting substrate 110 by inner wirings thereof.

In exemplary embodiments in accordance with principles of inventive concepts, the first semiconductor chip 200 may be mounted on the mounting substrate 110 by a flip-chip bonding method, for example. The first semiconductor chip 200 may be mounted on the mounting substrate 110 such that an active surface of the first semiconductor chip 200 faces the mounting substrate 110 and may be electrically connected to the mounting substrate 110 by bumps 210. The bumps 210 may be solder bumps, for example.

A plurality of the bumps 210 may be arranged on a plurality of the first bonding pads 122, respectively, such that the first semiconductor chip 200 and the mounting substrate 110 may be adhered to each other by the bumps 210. When the first semiconductor chip 200 is adhered to the mounting substrate 110, an adhesive may be underfilled between the first semiconductor chip 200 and the mounting substrate 110. The adhesive may include an epoxy material to reinforce a gap therebetween.

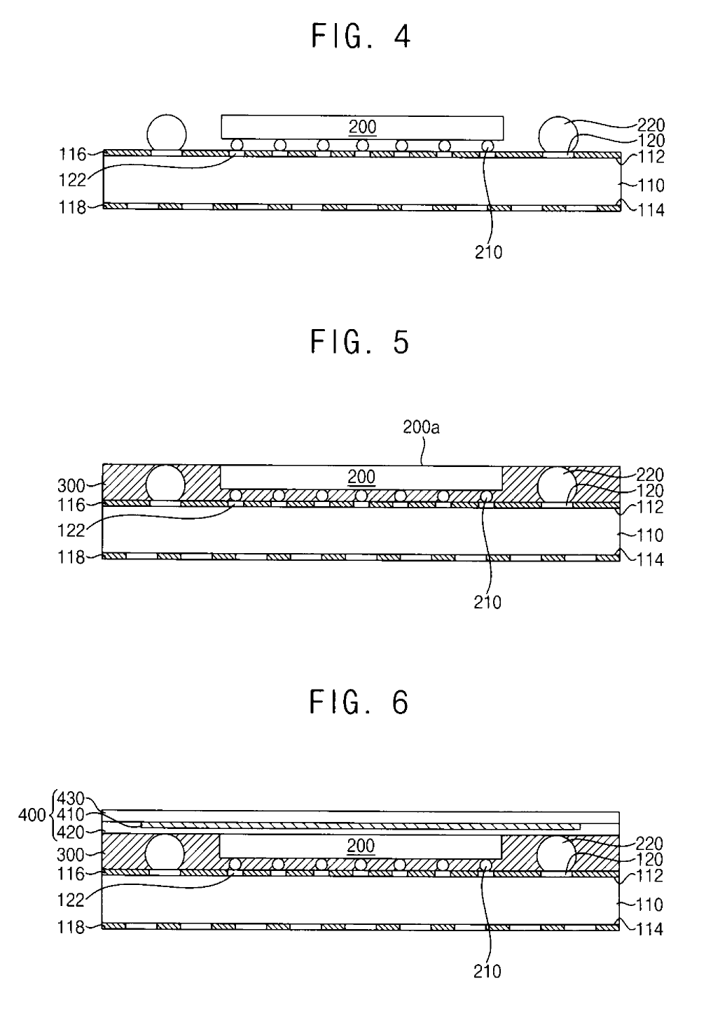

Referring to FIGS. 4 and 5, a first molding member 300, including first conductive connection members 200 formed therein, may be formed on the mounting substrate 110.

In an exemplary embodiment in accordance with principles of inventive concepts, the first conductive connection members 220 may be arranged on the first ground connection pads 120 in the peripheral region of the mounting substrate 110, respectively. The first conductive connection member 220 may include a solder ball, for example.

The first molding member 300 may be formed to cover at least a portion of the first semiconductor chip 200 on the upper surface 112 of the mounting substrate 110. The first molding member 300 may be formed to expose an upper surface 200a of the first semiconductor chip 200. Side surfaces of the first semiconductor chip 200 may be covered by the first molding member 300. The first molding member 300 may include epoxy molding compound (EMC), for example.

The first molding member 300 may be foaled to expose end portions of the first conductive connection members 220. Accordingly, the end portion of the first conductive connection member 220 may be exposed by the first molding member 300. In exemplary embodiments in accordance with principles of inventive concepts, the first molding member 300 may have a thickness of 0.18 mm or less.

Referring to FIG. 6, an EMI shield member 400 may be formed to cover the first semiconductor chip 200. In exemplary embodiments in accordance with principles of inventive concepts, the EMI shield member 400 may be formed on the first molding member 300 to cover the first semiconductor chip 200. The EMI shield member 400 may include a graphite layer 410 electrically connected to the first conductive connection member 220, a support layer 430 supporting the graphite layer 410 and a conductive adhesive layer 420 on the graphite layer 410. The graphite layer 410 may include a graphite tape, which may exhibit high heat conductivity and dissipation, and good EMI shielding performance, for example. The conductive adhesive layer 420 may include a conductive epoxy adhesive and the support layer 430 may include polyimide, for example. In exemplary embodiments in accordance with principles of inventive concepts, the EMI shield member 400 may have a thickness of 0.10 mm or less.

The graphite layer 410 may be adhered to the first molding member 300 by the conductive adhesive layer 420. The conductive adhesive layer 420 may make contact with the graphite layer 410 to electrically connect the graphite layer 410 and the first conductive connection member 220.

The first ground connection pads 120 may be electrically connected to the outer connection pads 130 on the lower surface 114 of the mounting substrate 110 by inner wirings. Accordingly, the EMI shield member 400 may be electrically connected to the outer connection pads 130 by the first conductive connection members 220.

Outer connection members 140, which may include a solder ball, may be formed on the outer connection pads 130 on the lower surface 114 of the mounting substrate 110 to complete a semiconductor package 100.

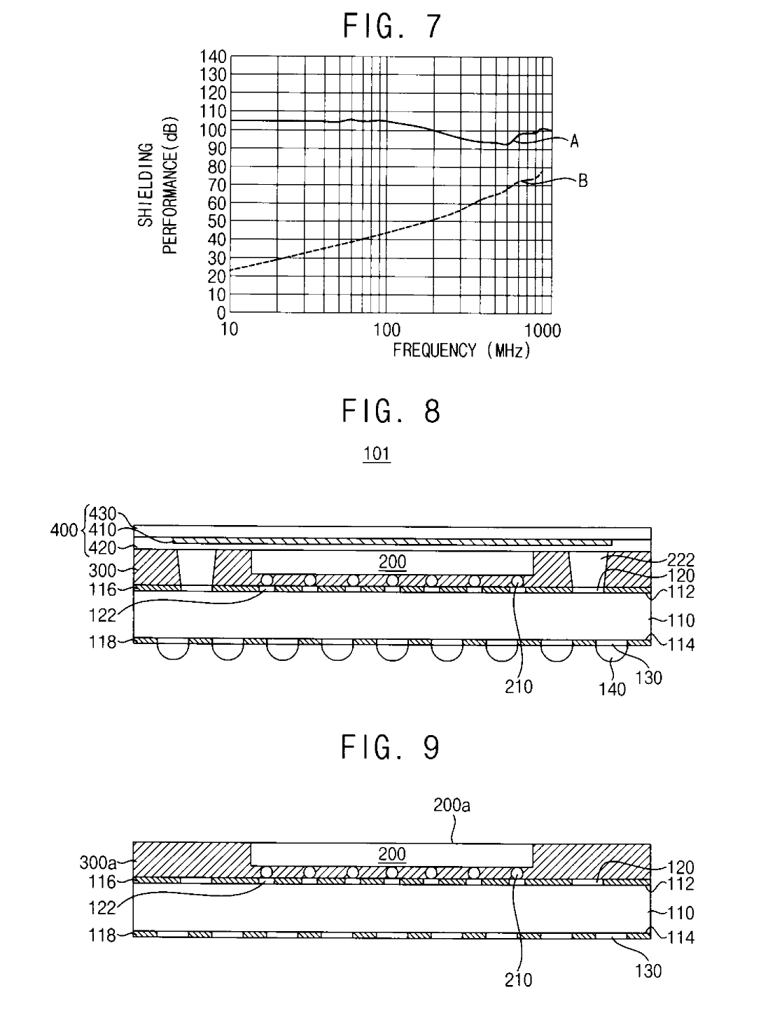

FIG. 7 is a graph illustrating EMI shielding performance of an exemplary embodiment of an EMI shield member including the graphite layer in accordance with principles of inventive concepts. FIG. 7 represents EMI shielding performance versus frequency for an exemplary embodiment that employs graphite tape. The curve A represents electric shielding performance and the curve B represents magnetic shielding performance. The EMI shielding performance may be expressed by −20 log(Vs/Vo) (dB). A shielding performance range above 60 dB may be considered a high level of protection.

As illustrated in FIG. 7, in an exemplary embodiment in accordance with principles of inventive concepts, the magnetic shielding performance of the graphite tape measured by EMI shielding test increases as the frequency increases, while the measured electric shielding performance of the graphite tape is constant as the frequency changes.

FIG. 8 is a cross-sectional view illustrating an exemplary embodiment of a semiconductor package in accordance with principles of inventive concepts. The semiconductor package may be substantially the same as, or similar to, that of FIG. 1, except for a first conductive connection member. Thus, like reference numerals refer to like elements, and, for the sake of clarity and brevity, detailed descriptions of like elements will be omitted herein.

Referring to FIG. 8, semiconductor package 101 may include a mounting substrate 110, a first semiconductor chip 200 mounted on the mounting substrate 110, a first molding member 300 covering at least a portion of the first semiconductor chip 200, at least one first conductive connection member 222 penetrating at least a portion of the first molding member 300 to protrude from the first molding member 300 and provided on at least one first ground connection pad 120, and an EMI shield member 400 covering the first semiconductor chip 200 and electrically connected to the first conductive connection members 222.

The first ground connection pads 120 for electrical connection with the EMI shield member 400 may be formed on an upper surface 112 of the mounting substrate 110 and may be arranged in a peripheral region outside a chip-mounting region of the mounting substrate 110, for example.

First bonding pads 122 for electrical connection with the first semiconductor chip 200 may be formed on the upper surface 112 of the mounting substrate 110 and may be arranged in the chip-mounting region of the mounting substrate 110.

In accordance with principles of inventive concepts, the first semiconductor chip 200 may be mounted on the mounting substrate 110 by a flip-chip bonding method. The first semiconductor chip 200 may be electrically connected to the mounting substrate 110 by bumps 210. Although it is not illustrated in the figure, an adhesive may be underfilled between the first semiconductor chip 200 and the mounting substrate 110.

The first molding member 300 may be formed on the upper surface 112 of the mounting substrate 110 to cover at least a portion of the first semiconductor chip 200 and to protect the first semiconductor chip 200. The first molding member 300 may be formed to expose an upper surface of the first semiconductor chip 200, for example.

In this exemplary embodiment, the first molding member 300 may include through-holes that expose the first ground connection pads 120 in the peripheral region of the mounting substrate 110 respectively. The through-holes may be filled with the first conductive connection members 222 respectively and first conductive connection member 222 may include a conductive material, for example, which may include a solder paste, silver, or epoxy, for example.

The first conductive connection members 222 may fill the through-holes in the first molding member 300 to protrude from the first molding member 300. The EMI shield member 400 may be provided on the first molding member 300 to make contact with the first conductive connection members 222 such that the EMI shield member 400 may be electrically connected to the first conductive connection members 222. The EMI shield member 400 may make contact with the exposed upper surface of the first semiconductor chip 200.

Accordingly, a graphite layer 410 of the EMI shield member 400 may be electrically connected to the first ground connection pads 120 by the first conductive connection members 222. The graphite layer 410 may exhibit high heat conductivity and dissipation, and good EMI shielding. In exemplary embodiments in accordance with principles of inventive concepts, the thickness of the semiconductor package 101 may be reduced while, at the same time, EMI shielding and heat dissipation may be enhanced.

Hereinafter, an exemplary method in accordance with principles of inventive concepts of manufacturing a semiconductor package such as that in FIG. 8 will be explained. To that end, FIGS. 9 to 12 are cross-sectional views illustrating of an exemplary embodiment of a method of manufacturing a semiconductor package in accordance with principles of inventive concepts. This exemplary method may be used to manufacture the semiconductor package illustrated in FIG. 8, however, its use is not limited thereto. The method may include processes substantially the same as, or similar to, the processes described with reference to FIGS. 2 to 6. Thus, like reference numerals refer to like elements, and, for the sake of brevity and clarity, detailed descriptions of like elements will not be repeated herein.

Referring to FIG. 9, processes the same as, or similar to, those that are illustrated with reference to FIGS. 2 to 4 may be performed to mount a first semiconductor chip 200 on a mounting substrate 110.

At least one first ground connection pad 120 and a plurality of first bonding pads 122 may be formed on an upper surface 112 of the mounting substrate 110. A plurality of outer connection pads 130 may be formed on a lower surface 114 of the mounting substrate 110. The first ground connection pads 120 may be arranged in a peripheral region of the mounting substrate 110. The first bonding pads 122 may be arranged in a chip-mounting region of the mounting substrate 110.

The first semiconductor chip 200 may be adhered to the chip-mounting region of the mounting substrate 110. The first semiconductor chip 200 may be electrically connected to the mounting substrate 110 by bumps 210. Although it is not illustrated in the figure, when the first semiconductor chip 200 is adhered to the mounting substrate 110, an adhesive may be underfilled between the first semiconductor chip 200 and the mounting substrate 110.

A first preliminary molding member 300a may be formed on the upper surface 112 of the mounting substrate 110 to cover at least a portion of the first semiconductor chip 200. The first preliminary molding member 300a may be formed to expose an upper surface 200a of the first semiconductor chip 200. The first preliminary molding member 300a may be formed in the peripheral region of the mounting substrate 110 to cover the first ground connection pads 120.

Referring to FIGS. 10 and 11, a first molding member 300 may be formed on the mounting substrate 110. The first molding member 300 may include a plurality of first conductive connection members 222 electrically connected to the first ground connection pads 120 in the peripheral region of the mounting substrate 110, for example.

The first preliminary molding member 300a may be partially removed to form through-holes 302 that expose the first ground connection pads 120 in the peripheral region of the mounting substrate 110 respectively. Through-holes 302 may be formed by a laser drilling process, for example. Accordingly, the first molding member 300 having the through-holes 302 may be formed on the mounting substrate 110.

The through-holes 302 of the first molding member 300 may be filled with a conductive material to form the first conductive connection members 222 that contact the first ground connection pads 120, respectively. The conductive material may include a solder paste, silver or epoxy, for example. The first conductive connection member 222 may be formed to protrude from the first molding member 300 by a predetermined distance, for example.

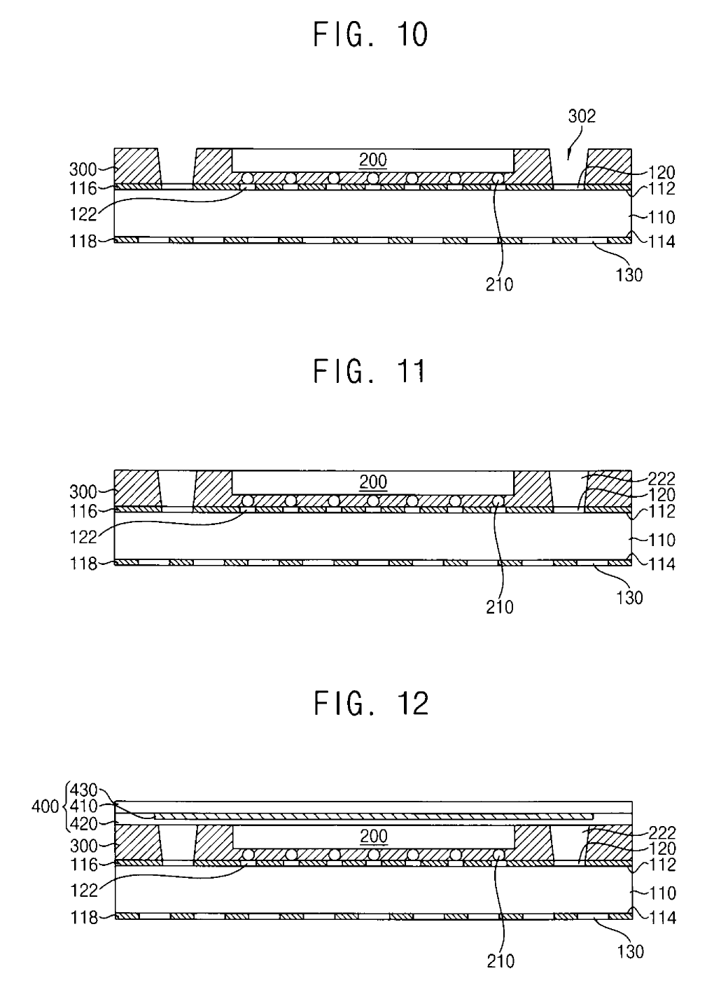

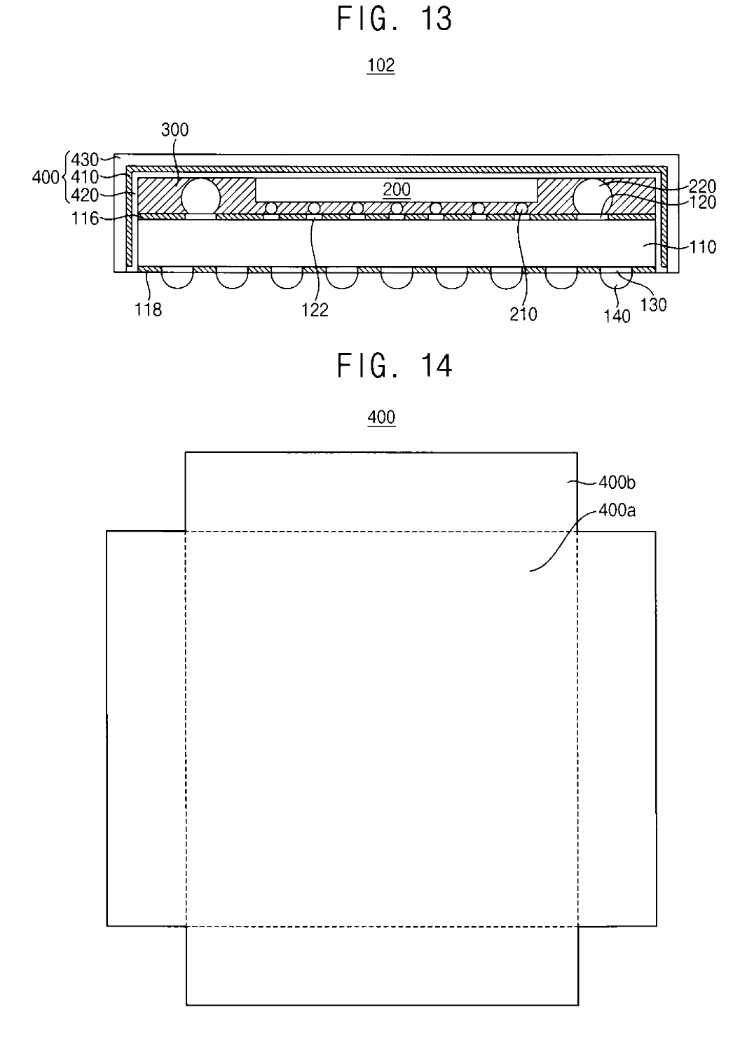

Referring to FIG. 12, an EMI shield member 400 may be formed to cover the first semiconductor chip 200. The EMI shield member 400 may be disposed on the first molding member 300 to cover the first semiconductor chip 200. The EMI shield member 400 may include a graphite layer 410 electrically connected to the first conductive connection member 220, a support layer 430 supporting the graphite layer 410, and a conductive adhesive layer 420 on the graphite layer 410.

The first ground connection pads 120 may be electrically connected to outer connection pads 130 on the lower surface 114 of the mounting substrate 110 by inner wirings. The EMI shield member 400 may be electrically connected to the outer connection pads 130 by the first conductive connection members 222.

Outer connection members such as solder balls, for example, may be formed on the outer connection pads 130 on the lower surface 114 of the mounting substrate 110, to complete the semiconductor package 101 in FIG. 8.

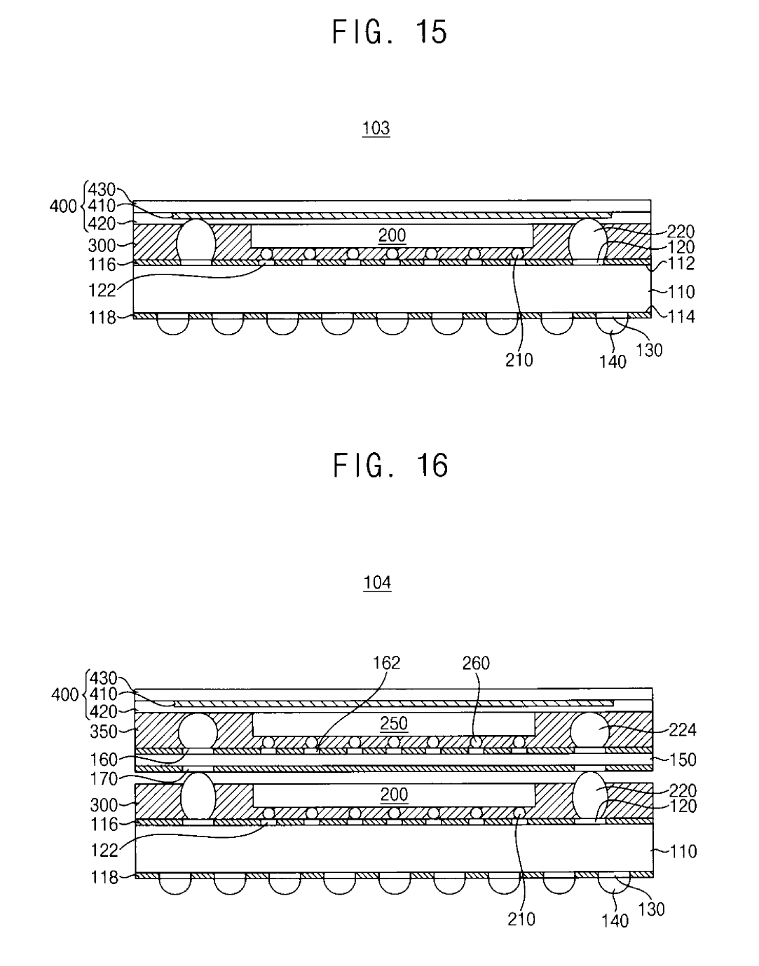

FIG. 13 is a cross-sectional view illustrating an exemplary embodiment of a semiconductor package in accordance with principles of inventive concepts. FIG. 14 is a plan view illustrating an EMI shield member of the semiconductor package in FIG. 13. The semiconductor package may be substantially the same as, or similar to, that of FIG. 1, except for the EMI shield member. Thus, like reference numerals refer to like elements, and, for brevity and clarity, detailed descriptions of like elements will not be repeated herein.

Referring to FIGS. 13 and 14, a semiconductor package 102 in accordance with principles of inventive concepts may include a mounting substrate 110, a first semiconductor chip on the mounting substrate 110, a first molding member 300 covering at least a portion of the first semiconductor chip 200, first conductive connection members 220 penetrating at least a portion of the first molding member 300 in a peripheral region of the mounting substrate 110, and an EMI shield member 400 covering the first semiconductor chip 200.

In this exemplary embodiment, the EMI shield member 400 may cover at least a portion of an outer side surface of the mounting substrate 110. As illustrated in FIG. 14, the EMI shield member 400 may include a first shielding portion 400a and a second shielding portion 400b.

The first shielding portion 400a may have a shape corresponding to an upper surface 112 of the mounting substrate 110 to cover the upper surface 112 of the mounting substrate 110. The second shielding portion 400b may extend from the first shield member 400a to cover the outer side surface of the mounting substrate 110.

In accordance with principles of inventive concepts, when the first shielding portion 400a is adhered to the first molding member 300 to cover the first semiconductor chip 200, the second shielding portion 400b may be bent and adhered to the outer side surface of the first molding member 300 such that the EMI shield member 400 may be adhered to an outer surface of the mounting substrate 110.

FIG. 15 is a cross-sectional view illustrating an exemplary embodiment of a semiconductor package 103 in accordance with principles of inventive concepts. The semiconductor package 103 may be substantially the same as, or similar to, that of FIG. 1, except for an EMI shield member. Thus, like reference numerals refer to like elements, and, for the sake of brevity and clarity, detailed descriptions of like elements will not be repeated herein. Semiconductor package 103 in accordance with principles of inventive concepts may include a mounting substrate 110, a first semiconductor chip on the mounting substrate 110, a first molding member 300 covering at least a portion of the first semiconductor chip 200, first conductive connection members 220 penetrating at least a portion of the first molding member 300 in a peripheral region of the mounting substrate 110, and an EMI shield member 400 covering the first semiconductor chip 200. EMI shield member 400 may include a graphite layer 410, a support layer 430 supporting the graphite layer 410, and an adhesive layer 420 on the graphite layer 410.

In this embodiment, the first conductive connection member 220 may be formed to protrude from the first molding member 300, with an end portion of the first conductive connection member 220 protruding from the first molding member 300 by a predetermined distance, for example.

The graphite layer 410 may be adhered to the first molding member 300 by the adhesive layer 420, which may include a non-conductive adhesive. Portions of the graphite layer 410 may be exposed by the adhesive layer 420 corresponding to positions of the first conductive connection members 220. Accordingly, the first conductive connection member 220 may make contact with the exposed portion of the graphite layer 410.

FIG. 16 is a cross-sectional view illustrating an exemplary embodiment of a semiconductor package 104 in accordance with principles of inventive concepts. The semiconductor package 104 may be substantially the same as, or similar to, that of FIG. 1, except for an additionally stacked semiconductor chip. Thus, like reference numerals refer to like elements, and, for clarity and brevity of description, detailed descriptions of those elements will not be repeated herein. Semiconductor package 104 may include a first package having a first semiconductor chip 200 and a second package having a second semiconductor chip 250 on the first package.

The first package may include a mounting substrate 110, the first semiconductor chip 200 mounted on the mounting substrate 110, a first molding member 300 covering at least a portion of the first semiconductor chip 200, and first conductive connection members 220 penetrating through at least a portion of the first molding member 300 around the first semiconductor chip 200. The second package may include a redistribution wiring substrate 150 stacked on the first molding member 300, the second semiconductor chip 250 mounted on the redistribution wiring substrate 150, a second molding member 350 covering at least a portion of the second semiconductor chip 250, second conductive connection members 224 penetrating at least a portion of the second molding member, and an EMI shield member 400 covering the first and second semiconductor chips 200 and 250.

The redistribution wiring substrate 150 may have an upper surface and a lower surface facing each other. The redistribution wiring substrate 150 may be a multi-layered circuit board having various circuits and vias therein and may have a chip-mounting region and a peripheral region, for example. The second semiconductor chip 250 may be mounted on the chip-mounting region of the redistribution wiring substrate 150. At least one second semiconductor chip 250 may be mounted on the redistribution wiring substrate 150, for example.

Second ground connection pads 160 for electrical connection with the EMI shield member 400 may be formed on the upper surface of the redistribution wiring substrate 150. In exemplary embodiments in accordance with principles of inventive concepts the second ground connection pads 160 may be arranged in the peripheral region outside the chip-mounting region of the redistribution wiring substrate 150.

Second bonding pads 162 for electrical connection with the second semiconductor chip 250 may be formed on the upper surface of the redistribution wiring substrate 150. The second bonding pads 162 may be arranged in the chip-mounting region, for example.

Redistribution wiring connection pads 170 for electrical connection with the first conductive connection members 220 may be formed on the lower surface of the redistribution wiring substrate 150.

In exemplary embodiments in accordance with principles of inventive concepts, a plurality of the second bonding pads 162 and a plurality of the second ground connection pads 160 may be exposed by insulation layer patterns on the redistribution wiring substrate 150. The insulation layer pattern may include silicon oxide, silicon nitride, or silicon oxynitride, for example.

The second bonding pads 162 and the second ground connection pads 160 may be electrically connected to the redistribution wiring connection pads 170 by inner wirings of the redistribution wiring substrate 150.

The second semiconductor chip 250 may be mounted on the redistribution wiring substrate 150 such that an active surface of the second semiconductor chip 250 faces the redistribution wiring substrate 150. For example, the second semiconductor chip 250 may be electrically connected to the redistribution wiring substrate 150 by bumps 260.

The first conductive connection members 220 may be arranged on first ground connection pads 120 in the peripheral region of the mounting substrate 110 and, in exemplary embodiments, the first conductive connection members 220 may be solder balls. The first conductive connection members 220 may protrude from the first molding member 300 with end portions protruding by a predetermined distance, for example.

The redistribution wiring substrate 150 having the second semiconductor chip 250 stacked thereon may be stacked on the first molding member 300 by the first conductive connection members 220. The protruding end portions of the first conductive connection members 220 may be electrically connected to the redistribution wiring connection pads 170 on the lower surface of the redistribution wiring substrate 150, respectively. Although it is not illustrated in the figure, the redistribution wiring substrate 150 may be adhered to upper surfaces of the first molding member 300 and/or the first semiconductor chip by an adhesive layer. Accordingly, the redistribution wiring substrate 150 may be electrically connected to the first conductive connection members 220.

The second conductive connection members 224 may be arranged on the second ground connection pads 160 in the peripheral region of the redistribution wiring substrate 150, respectively and may include a solder ball, for example.

The second molding member 350 may be formed on the upper surface of the redistribution wiring substrate 150 to cover at least a portion of the second semiconductor chip 250 and to protect the second semiconductor chip 250.

The second molding member 350 may be formed to expose an upper surface of the second semiconductor chip 250 and end portions of the second conductive connection members 224. That is, the end portions of the second conductive connection members 224 may be exposed by the second molding member 350. Side surfaces of the second semiconductor chip 250 may be covered by the second molding member 350.

In accordance with principles of inventive concepts, the EMI shield member 400 may be disposed over the second molding member 350 to cover the first and the second semiconductor chips 200 and 250 and may make contact with the exposed upper surface of the second semiconductor chip 250.

The EMI shield member 400 may include a graphite layer 410 electrically connected to the second conductive connection member 224, a support layer 430 supporting the graphite layer 410 and a conductive adhesive layer 420 on the graphite layer 410, for example. The graphite layer 410 may include a graphite tape featuring high heat conductivity and/or dissipation and good EMI shielding. The conductive adhesive layer 420 may include a conductive epoxy adhesive and the support layer 430 may include polyimide.

The graphite layer 410 may be adhered to the second molding member 350 by the conductive adhesive layer 420, which may make contact with the second conductive connection member 224 to electrically connect the graphite layer 410 and the second conductive connection member 224, for example. Accordingly, the EMI shield member 400 may be electrically connected to outer connection members 140 on outer connection pads 130 of the mounting substrate 110 by the first and the second conductive connection members 220 and 224, respectively.

In this exemplary embodiment, the semiconductor package 104 may be a system in package (SIP). The first semiconductor chip 200 may be a logic chip including a logic circuit and the second semiconductor chip 250 may be a memory chip including a memory circuit. The memory circuit may include a memory cell region for storing data and/or a memory logic region for operating the memory chip, for example.

The first semiconductor chip 200 may include a circuit portion having functional circuits that may include a transistor or a passive device such as resistor or capacitor, for example. The functional circuits may include a memory control circuit, an external input/output circuit, a micro input/output circuit and/or an additional functional circuit, for example. The memory control circuit may provide a data signal and/or a memory control signal for operating the second semiconductor chip 250. The memory control signal may include address signal, command signal, or clock signal, for example.

In this exemplary embodiment, data signal connection pads and control signal connection pads may be formed on the upper surface of the mounting substrate 110. The data signal connection pads and the control signal connection pads may be arranged on the peripheral region together with the first ground connection pads 120.

Additionally, conductive connection members may be arranged on the data signal connection pads and the control signal connection pads. The conductive connection members may be solder balls like the first conductive connection members 220, for example.

The conductive connection members on the data signal connection pads and the control signal connection pads may protrude from the first molding member 300 and the protruding end portions may make contact with the redistribution wiring connection pads 170 on the lower surface of the redistribution wiring substrate 150, respectively, and may be electrically connected to the redistribution wiring substrate 150, for example. In this manner, the conductive connection members on the data signal connection pads and the control signal connection pads may be used as an electrical path for transmitting a signal or power required to operate the second semiconductor chip 250. The signal may include a data signal or a control signal and the power may include a power voltage (VDD) and a ground voltage (VSS), for example.

In this exemplary embodiment, the data signal and/or the control signal may be transmitted from the memory control circuit of the first semiconductor chip 200 to the second semiconductor chip 250. The power voltage (VDD) and/or the ground voltage (VSS) may be supplied to the second semiconductor chip 250 through the mounting substrate 110.

Hereinafter, an exemplary method in accordance with principles of inventive concepts of manufacturing a semiconductor package such as that described in the discussion related to FIG. 16 will be explained.

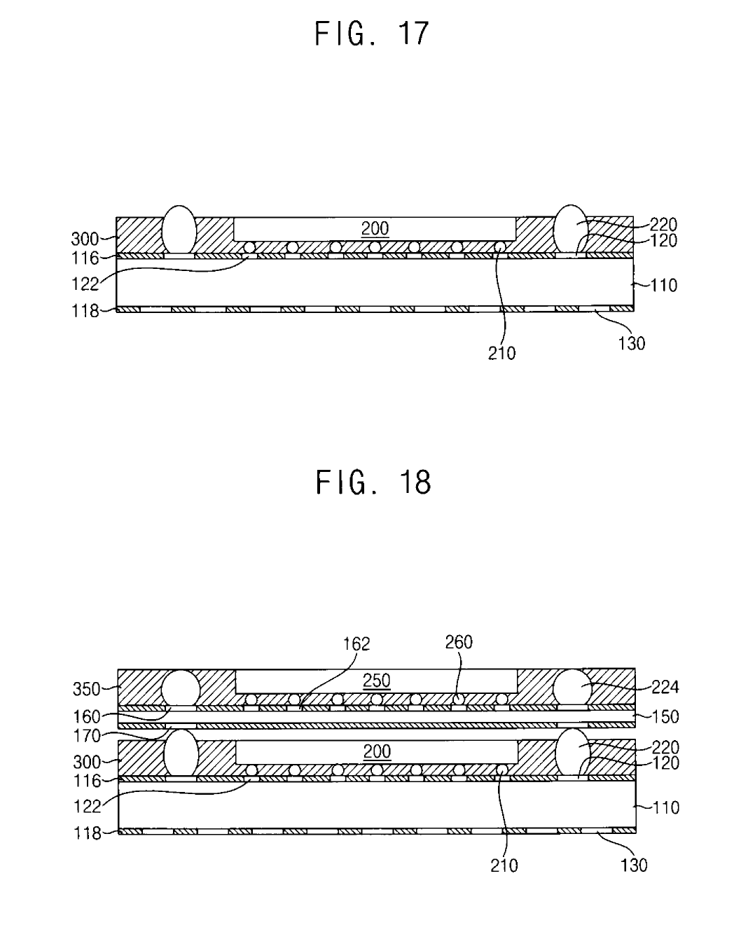

FIGS. 17 to 19 are cross-sectional views illustrating an exemplary method of manufacturing a semiconductor package in accordance with principles of inventive concepts. The method may be used, for example, to manufacture a semiconductor package such as package 104 illustrated in FIG. 16, however, the method is not limited thereto. The method may be substantially the same as or similar to the processes explained with reference to FIGS. 2 to 6. Thus, like reference numerals refer to like elements, and, for brevity and clarity of description, detailed descriptions of those elements will not be repeated herein.

Referring to FIG. 17, processes the same as or similar to the processes explained with reference to FIG. 2, FIG. 4 and FIG. 5 may be performed such that a first semiconductor chip 200 may be mounted on a mounting substrate 110 and a first molding member 300 may be formed to cover at least a portion of the first semiconductor chip 200.

A plurality of first ground connection pads 120 and a plurality of first bonding pads 122 may be formed on an upper surface 112 of the mounting substrate 110. A plurality of outer connection pads 130 may be formed on a lower surface of the mounting substrate 110. The first ground connection pads 120 may be arranged in a peripheral region of the mounting substrate 110 and the first bonding pads 122 may be arranged in a chip-mounting region of the mounting substrate 110, for example. Data signal connection pads and control signal connection pads may be formed on the upper surface 112 of the mounting substrate 110. The data signal connection pads and control signal connection pads may be arranged in the peripheral region of the mounting substrate 110 together with the first ground connection pads 120, for example.

A first semiconductor chip 200 may be mounted on the chip-mounting region of the mounting substrate 110 and may be electrically connected to the mounting substrate 110 by bumps 210. Although it is not illustrated in the figure, when the first semiconductor chip 200 is adhered to the mounting substrate 110, an adhesive may be underfilled between the first semiconductor chip 200 and the mounting substrate 110.

First conductive connection members 220 may be disposed on the first ground connection pads 120 in the peripheral region and may be solder balls, for example. The first conductive connection members 220 may protrude from the first molding member 300, with end portions protruding from the first molding member 300 by a predetermined distance.

In exemplary embodiments in accordance with principles of inventive concepts, conductive connection members may be arranged on the data signal connection pads and the control signal connection pads. The conductive connection members may be solder balls like the first conductive connection members 220. The conductive connection members on the data signal connection pads and the control signal connection pads may protrude from the first molding member 300, for example.

Referring to FIG. 18, a redistribution wiring substrate 150 may be stacked on the first molding member 300 to be electrically connected to the first conductive connection members 220. Second ground connection pads 160 may be arranged on an upper surface of the redistribution wiring substrate 150 in a peripheral region thereof. Second bonding pads 162 may be arranged on the upper surface of the redistribution wiring substrate 150 in a chip-mounting region thereof. Redistribution wiring connection pads 170 may be formed on a lower surface of the redistribution wiring substrate 150 to be electrically connected to the first conductive connection members 220.

A second semiconductor chip 250 may be mounted on the redistribution wiring substrate 150 such that active surface thereof faces the redistribution wiring substrate 150. The second semiconductor chip 250 may be electrically connected to the redistribution wiring substrate 150 by bumps 260, for example.

Second conductive connection members 224 may be arranged on the second ground connection pads 160 in the peripheral region of the redistribution wiring substrate 150 and may be solder balls, for example.

A second molding member 350 may be formed on the redistribution wiring substrate 150 to cover at least a portion of the second semiconductor chip 250. The second molding member 350 may be formed to expose end portions of the second conductive connection members 224. End portions of the second conductive connection members may be exposed by the second molding member 350.

As illustrated in FIG. 18, the redistribution wiring substrate 150 having the second semiconductor chip 250 mounted thereon may be stacked on the first molding member 300 by the first conductive connection members 220. The protruding end portions of the first conductive connection members 220 may make contact with the redistribution wiring connection pads 170 on the lower surface of the redistribution wiring substrate 150 and be electrically connected to the redistribution wiring substrate 150. Although it is not illustrated in the figure, the redistribution wiring substrate may be adhered to upper surfaces of the first molding member 300 and/or the first semiconductor chip 200. That is, in exemplary embodiments in accordance with principles of inventive concepts, the end portions of the first conductive connection members 220 protruding from the first molding member 300 may make contact with the redistribution wiring connection pads 170 on the lower surface of the redistribution wiring substrate 150 and be electrically connected to the redistribution wiring substrate 150.

The conductive connection members on the data signal connection pads and the control signal connection pads may make contact with the redistribution wiring connection pads on the lower surface of the redistribution wiring substrate 150 and be electrically connected to the redistribution wiring substrate 150, for example.

Referring to FIG. 19, in exemplary embodiments in accordance with principles of inventive concepts, an EMI shield member 400 may be formed to cover the first and the second semiconductor chips 200 and 250. The EMI shield member 400 may be disposed on the second molding member 350 and may include a graphite layer 410 electrically connected to the second conductive connection member 224, a support layer 430 supporting the graphite layer 410 and a conductive adhesive layer 420 on the graphite layer 410.

The graphite layer 410 may be adhered to the second molding member 350 by the conductive adhesive layer 420. The conductive adhesive layer 420 may make contact with the second conductive connection member 224 to electrically connect the graphite layer 410 and the second conductive connection member 224.

Outer connection members (not shown) may be formed on the outer connection pads 130 on the lower surface 114 of the mounting substrate 110 to complete the semiconductor package 104. Accordingly, the EMI shield member 400 may be electrically connected to the outer connection members (not shown) on the outer connection pads 130 by the first and the second conductive connection members 220 and 224.

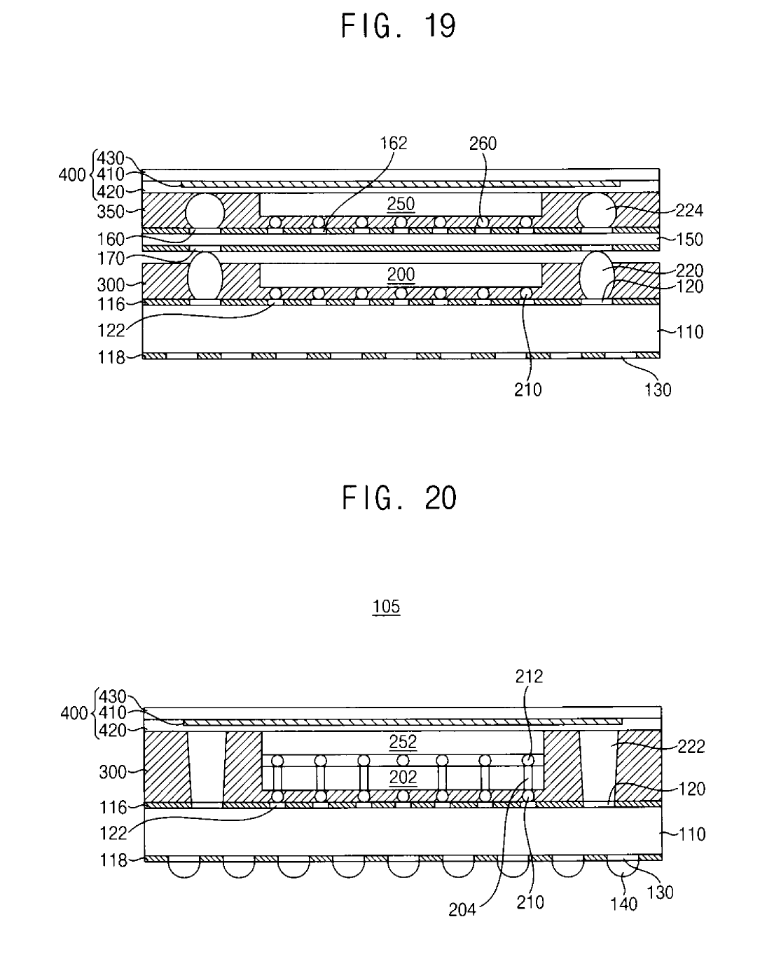

FIG. 20 is a cross-sectional view illustrating an exemplary embodiment of a semiconductor package 105 in accordance with principles of inventive concepts. The semiconductor package 105 may be substantially the same as or similar to that of FIG. 8, except for the structure of the stacked semiconductor chip. Thus, like reference numerals refer to like elements, and, for brevity and clarity, detailed descriptions of those elements will not be repeated herein.

Referring to FIG. 20, a semiconductor package 105 may include a mounting substrate 110, a first semiconductor chip 202 mounted on the mounting substrate 110, a third semiconductor chip 252 stacked on the first semiconductor chip 202, a first molding member 300 covering at least portions of the first and the third semiconductor chips 202 and 252, a plurality of first conductive connection members 222 penetrating at least a portion of the first molding member 300 and provided on a plurality of first ground connection pads 120 in a peripheral region of the mounting substrate 110, and an EMI shield member 400 covering the first and the third semiconductor chips 202 and 252 and electrically connected to the first connection member 222.

The third semiconductor chip 252 may be stacked on the first semiconductor chip 202 and may be electrically connected to the first semiconductor chip 202 by a plurality of bumps 212. The first semiconductor chip 202 may include plugs 204 penetrating the first semiconductor chip 202. A through-electrode called as through silicon via (TSV) may be used as the plugs 204.

The bumps 212 may be arranged on end portions of the through-electrodes of the first semiconductor chip 202 to electrically connect the first semiconductor chip 202 and the third semiconductor chip 252. Thus, the third semiconductor chip 202 may be electrically connected to the first semiconductor chip 202 by a plurality of the through-electrodes penetrating through the first semiconductor chip 202.

The first molding member 300 may be formed on an upper surface of the mounting substrate 110 to cover portions of the first and the third semiconductor chips 202 and 252. The first molding member 300 may be formed to expose an upper surface of the second semiconductor chip 252.

The first molding member 300 may have through-holes that expose the first ground connection pads 120 in the peripheral region of the mounting substrate 110. The through-holes may be filled with the first conductive connection members 222. The first conductive connection members 222 may include a conductive material such as a conductive paste, for example.

The first conductive connection members 222 may fill the through-holes to protrude from the first molding member 300. The EMI shield member 400 may make contact with the first conductive connection members 222 protruding from the first molding member 300 to be electrically connected to the first conductive connection members 222. Additionally, the EMI shield member 400 may make contact with the exposed upper surface of the third semiconductor chip 252.

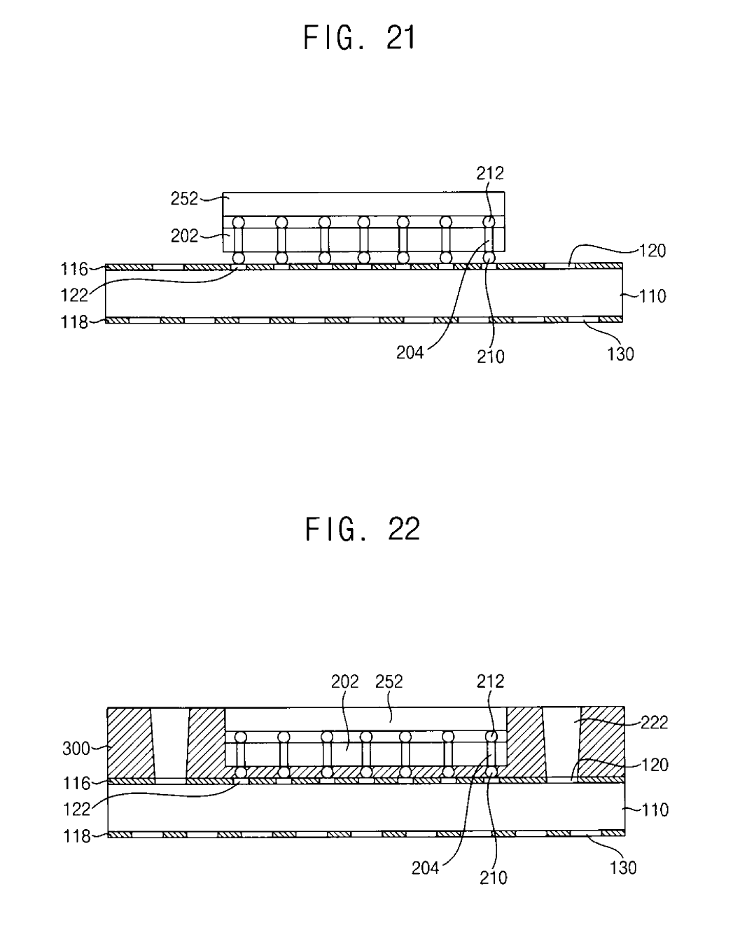

Hereinafter, an exemplary embodiment of a method in accordance with principles of inventive concepts of manufacturing a semiconductor package such as that in FIG. 20 will be explained. To that end, FIGS. 21 to 23 are cross-sectional views illustrating an exemplary method of manufacturing a semiconductor package in accordance with principles of inventive concepts. The method may be used to manufacture semiconductor packages such as that illustrated in FIG. 20, for example. The method may be substantially the same as or similar to those of FIGS. 9 to 12. Thus, like reference numerals refer to like elements, and, for brevity and clarity, detailed descriptions of those elements will not be repeated herein.

Referring to FIG. 21, first and third semiconductor chips 202 and 252 may be stacked on a mounting substrate 110. The third semiconductor chip 252 may be stacked on the first semiconductor chip 202 by a plurality of bumps 212, for example. The first semiconductor chip 202 may include plugs 204 penetrating through the first semiconductor chip 202. A through-electrode referred to as through silicon via (TSV) may be used as the plugs 204, for example.

The bumps 212 may be disposed on end portions of the through-electrodes of the first semiconductor chip 202, respectively. The third semiconductor chip 252 may be stacked on the first semiconductor chip 202 by a reflow process, for example. The third semiconductor chip 252 may be electrically connected to the first semiconductor chip 202 by a plurality of the through-electrodes penetrating through the first semiconductor chip 202.

The first and the third semiconductor chips 202 and 252 may be mounted on the mounting substrate 110 and the first semiconductor chip 202 may be electrically connected to the mounting substrate 110 by bumps 210, for example.

Referring to FIG. 22, a first molding member 300 may be formed on an upper surface 112 of the mounting substrate 110. The first molding member 300 may have first conductive connection members 222 for electrical connection with first ground connection pads 120.

A first preliminary molding member may be formed on the upper surface 112 of the mounting substrate 110 to cover at least portions of the first and the third semiconductor chips 202 and 252 and may be formed to expose an upper surface of the third semiconductor chip 252. The first preliminary molding member may cover side surfaces of the first and the third semiconductor chips 202 and 252 and may be formed in the peripheral region of the mounting substrate 110 to cover the first ground connection pads 120.

The first preliminary molding member may be partially removed to form through-holes that expose the first ground connection pads 120 in the peripheral region respectively. The through-holes may be formed by a laser drilling process, for example. Accordingly, the first molding member 300 having the through-holes therein may be formed on the mounting substrate 110.

The through-holes of the first molding member 300 may be filled up with a conductive material to form the first conductive connection members 222 that contact the first ground connection pads 120 respectively. The conductive material may include a conductive paste, for example. The first conductive connection members 222 may be formed to protrude from the first molding member 300.

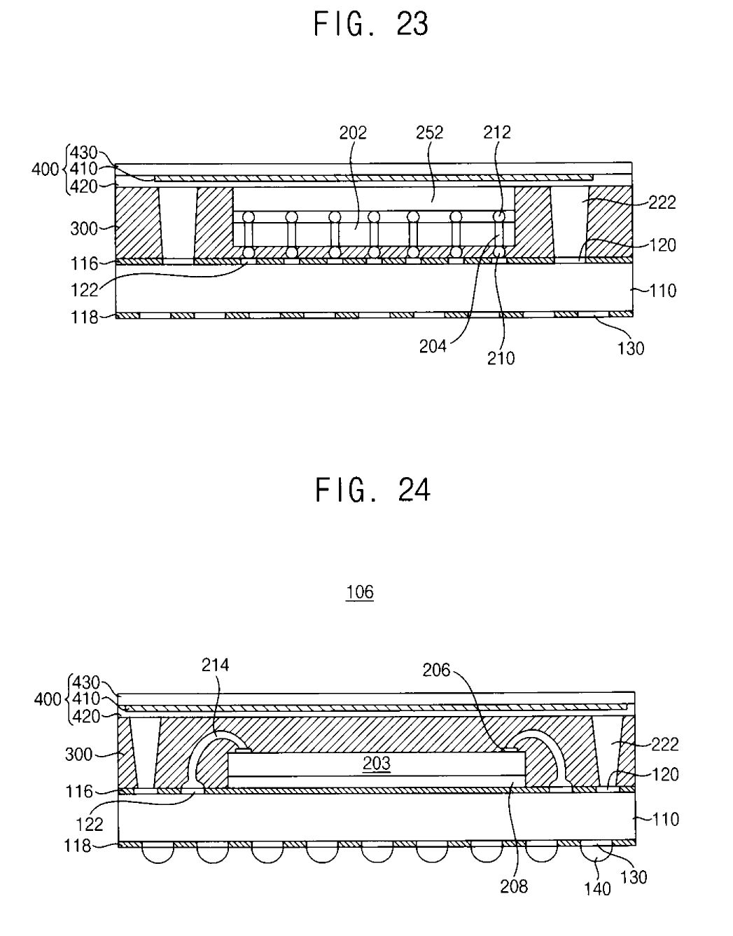

Referring to FIG. 23, an EMI shield member 400 may be formed to cover the first and the third semiconductor chips 202 and 252 and may be disposed on the first molding member 300. The EMI shield member 400 may include a graphite layer 410, a support layer supporting the graphite layer 410, and a conductive adhesive layer 420 on the graphite layer 410, for example.

The graphite layer 410 may be adhered to the first molding member 300 by the conductive adhesive layer 420, which may make contact with the first conductive connection member 220 to electrically connect the graphite layer 410 and the first conductive connection member 220, for example.

The first ground connection pads 120 may be electrically connected to outer connection pads 130 on a lower surface of the mounting substrate 110 by inner wirings thereof. Accordingly, in an exemplary embodiment in accordance with principles of inventive concepts, the EMI shield member 400 may be electrically connected to the outer connection pads 130 by the first conductive connection members 222.

Outer connection members, which may include, solder balls, for example, may be formed on the outer connection pads 130 on the lower surface 114 of the mounting substrate 110 to complete the semiconductor package 105 in FIG. 20.

FIG. 24 is a cross-sectional view illustrating an exemplary embodiment of a semiconductor package 106 in accordance with principles of inventive concepts. The semiconductor package 106 may be substantially the same as or similar to that of FIG. 8, except for a connection structure of the mounting substrate and the semiconductor chip. Thus, like reference numerals refer to like elements, and, for brevity and clarity, detailed descriptions of those elements will not be repeated herein.

Referring to FIG. 24, a semiconductor package 106 may include a mounting substrate 110, a first semiconductor chip 203 mounted on the mounting substrate 110, a first molding member 300 covering at least a portion of the first semiconductor chip 203, a plurality of first conductive connection members 222 on a plurality of first ground connection pads 120 in a peripheral region of the mounting substrate 110 and penetrating at least a portion of the first molding member 300, and an EMI shield member 400 covering the first semiconductor chip 203 and electrically connected to the first conductive connection members 222.

The first semiconductor chip 203 may be adhered to the mounting substrate 110 by an adhesive layer 208. Chip pads 206 may be formed on an upper surface of the first semiconductor chip 203. Bonding wires 214 may be drawn from first bonding pads 122 to be connected to the chip pads 206 of the first semiconductor chip 203, respectively. In this manner, the first semiconductor chip 203 may be electrically connected to the mounting substrate 110 by the bonding wires 214.

The first molding member 300 may be fowled on an upper surface 112 of the mounting substrate 110 to cover the first semiconductor chip 203 and may have through-holes that expose the first ground connection pads 120 in the peripheral region of the mounting substrate 110 respectively. The through-holes may be filled with the first conductive connection members 222, which may include a conductive material, such as a conductive paste, which fills the through-holes.

The first conductive connection members 222 may fill the through-holes to protrude from the first molding member 300. The EMI shield member 400 may be formed on the first molding member 300 to make contact with the first conductive connection members 222 protruding from the first molding member 300 and to be electrically connected to first conductive connection members 222.

Hereinafter, an exemplary method in accordance with principles of inventive concepts of manufacturing a semiconductor package such as that in FIG. 24 will be explained.

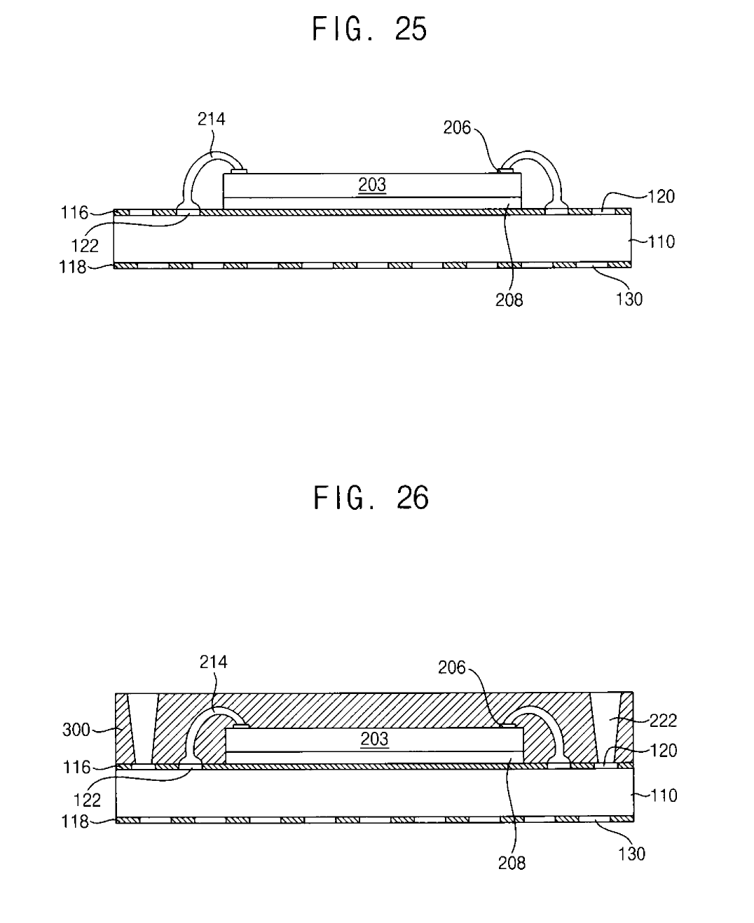

FIGS. 25 and 26 are cross-sectional views illustrating an exemplary method of manufacturing the semiconductor package 106 in accordance with principles of inventive concepts. The method may be used to manufacture the semiconductor package illustrated in FIG. 24, for example. The method may be substantially the same as or similar to the processes that explained with reference to FIGS. 9 to 12. Thus, like reference numerals refer to like elements, and, for brevity and clarity, detailed descriptions of those elements will not be repeated herein.

Referring to FIG. 25, a first semiconductor chip 230 may be stacked on a mounting substrate 110. The first semiconductor chip 230 may be adhered to the mounting substrate 110 using an adhesive layer 208. The mounting substrate 110 and the first semiconductor chip 203 may be electrically connected to each other by a plurality of bonding wires 214. The bonding wires 214 may be drawn to first bonding pads 122 of the mounting substrate 110 to be connected to chip pads 206 of the first semiconductor chip 203. The first semiconductor chip 203 may be electrically connected to the mounting substrate 110 by the bonding wires 214.

Referring to FIG. 26, a first molding member 300 may be formed on the mounting substrate 110. The first molding member 300 may have first conductive connection members 222 for electrical connection with first ground connection pads 120

A first preliminary molding member may be formed to cover the first semiconductor chip 203 on an upper surface 112 of the mounting substrate 110. The first preliminary molding member may be partially removed to form through-holes that expose the first ground connection pads 120 in the peripheral region of the mounting substrate 110. The through-holes may be formed by a laser drilling process, for example. The first molding member 300 having the through-holes may be formed on the mounting substrate 110.

The through-holes of the first molding member 300 may be filled with a conductive material to form the first conductive connection members 222 that contact the first ground connection pads 120 respectively. The conductive material may include a conductive paste. Upper portions of the first conductive connection members 222 may be formed to be exposed from the first molding member 300.

Referring again to FIG. 24, an EMI shield member 400 may be formed to cover the first semiconductor chip 203 to be electrically connected to the first conductive connection members 222. Outer connection members 140 may be formed on outer connection pads 130 on a lower surface 114 of the mounting substrate 110 to complete the semiconductor package 106.

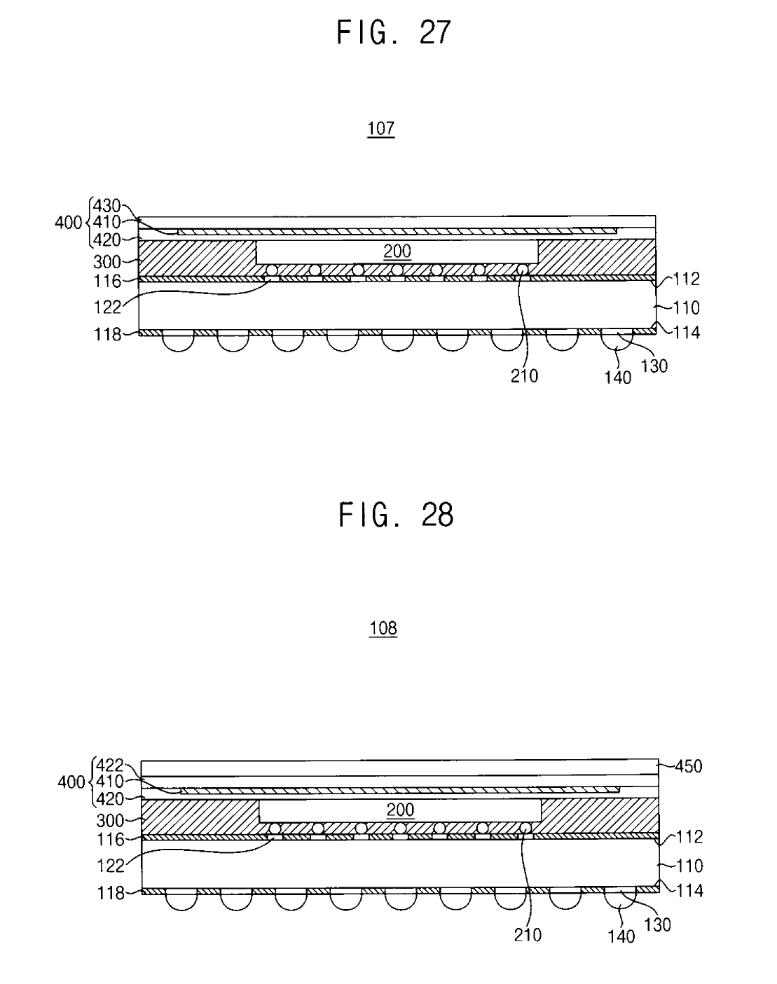

FIG. 27 is a cross-sectional view illustrating an exemplary embodiment of a semiconductor package in accordance with principles of inventive concepts. The semiconductor package may be substantially the same as or similar to that of FIG. 1, except for a connecting structure of an EMI shield member. Thus, like reference numerals refer to like elements, and, for clarity and brevity, detailed descriptions of those elements will not be repeated herein.

Referring to FIG. 27, a semiconductor package 107 may include a mounting substrate 100, a first semiconductor chip 200 mounted on the mounting substrate 100, a first molding member 300 exposing an upper surface of the first semiconductor chip 200 on the mounting substrate 110, and an EMI shield member 400 including a graphite layer 410 provided on the first molding member 300 and covering the first semiconductor chip 200.

The first semiconductor chip 200 may be arranged in a chip-mounting region of the mounting substrate 110. The first semiconductor chip 200 may be electrically connected to the mounting substrate 110 by a plurality of bumps 210 on first bonding pads 122.

The first molding member 300 may be formed on an upper surface of the mounting substrate 110 to cover the first semiconductor chip 200 and may be formed to expose the upper surface of the first semiconductor chip 200.

The EMI shield member 400 may be disposed on the first molding member 300 to cover the first semiconductor chip 200. The EMI shield member 400 may make contact with the upper surface of the first semiconductor chip 200 exposed by the first molding member 300.

The EMI shield member 400 may include the graphite layer 410 covering the first semiconductor chip 200, a support layer supporting the graphite layer 410, and an adhesive layer 420 on the graphite layer 410. The graphite layer 410 may be adhered to the first molding member 300 by the adhesive layer 420.

In this exemplary embodiment, a first conductive connection member as in FIG. 1 may not be included in the semiconductor package 107, EMI shield member 400 may not be electrically connected to the ground connection pad of the mounting substrate 110, and EMI shield member 400 may be insulated from the mounting substrate 110. The graphite layer 410 of the EMI shield member 400 may have a selective effective shielding level with respect to a specific frequency range, for example.

FIG. 28 is a cross-sectional view illustrating an exemplary embodiment of a semiconductor package 108 in accordance with principles of inventive concepts. The semiconductor package 108 may be substantially the same as or similar to that of FIG. 27, except for an EMI shield member and an additional heat dissipation plate. Thus, like reference numerals refer to like elements, and, for brevity and clarity, detailed descriptions of those elements will not be repeated herein.

Referring to FIG. 28, a semiconductor package 108 may include a mounting substrate 110, a first semiconductor chip 200 mounted on the mounting substrate 110, a first molding member 300 on the mounting substrate to expose an upper surface of the first semiconductor chip, an EMI shield member 400 including a graphite layer 410 on the first molding member 300 to cover the first semiconductor chip 200, and a heat dissipation plate 450 on the EMI shield member 400.

The EMI shield member 400 may be disposed on the first molding member 300 to cover the first semiconductor chip 200 and may make contact with the upper surface of the first semiconductor chip 200 exposed by the first molding member 300.

The EMI shield member 400 may include the graphite layer 410 covering the first semiconductor chip 200, and first and second adhesive layers 420 and 422 on upper and lower surfaces of the graphite layer 410. The first and second adhesive layers 420 and 422 may include a non-conductive adhesive, for example. The graphite layer 410 may be adhered to the first molding member 300 by the first adhesive layer 420.

In exemplary embodiments, the EMI shield member 400 may have a thickness of from 20 μm to 80 μm. The graphite layer 410 may have a thickness of from 30 μm to 40 μm. The first and second adhesive layers 420 and 422 may have a thickness of from 5 μm to 20 μm.

The heat dissipation plate 450 may be adhered to the EMI shield member 400 and may include a metal plate having copper, for example. The heat dissipation plate 450 may be adhered to the graphite layer 410 of the EMI shield member 400 by the second adhesive layer 422.

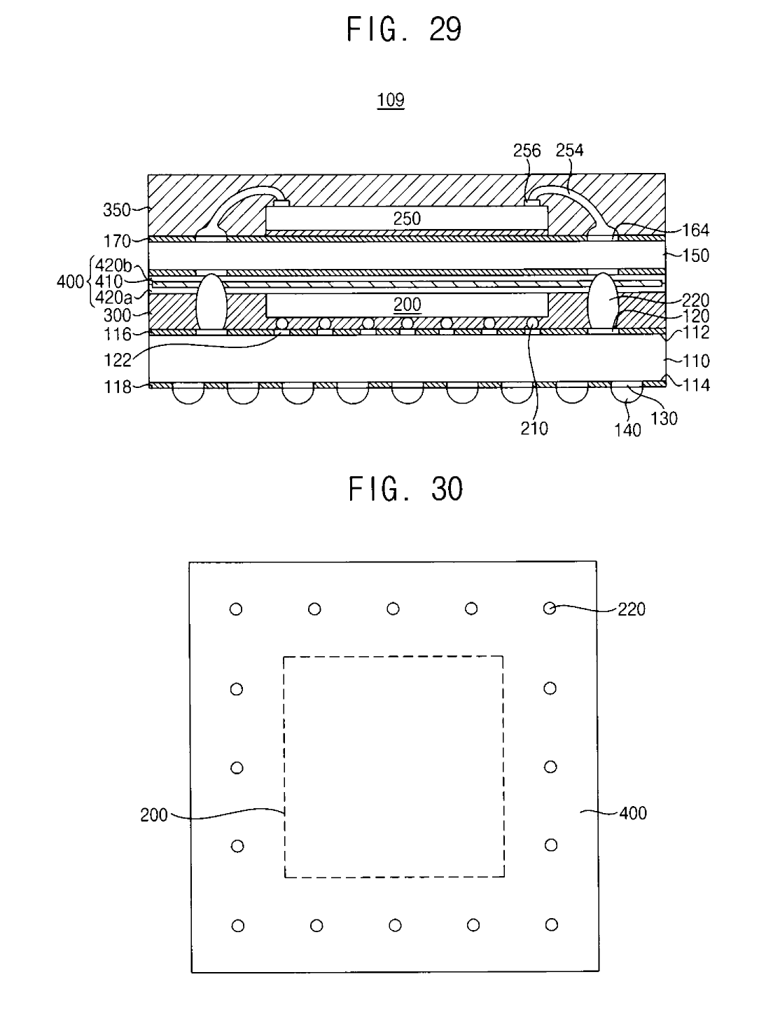

FIG. 29 is a cross-sectional view illustrating an exemplary embodiment of a semiconductor package 109 in accordance with principles of inventive concepts. FIG. 30 is a plan view illustrating an EMI shield member interposed between first and second packages in FIG. 29. The semiconductor package may be substantially the same as or similar to that of FIG. 16, except for a position of the EMI shield. Thus, like reference numerals refer to like elements, and, for clarity and brevity, detailed descriptions of those elements will not be repeated herein.

Referring to FIGS. 29 and 30, a semiconductor package 109 may include a first package and a second package stacked over the first package, and an EMI shield member interposed between the first and second packages.

The first package may include a mounting substrate 110, a first semiconductor chip 200 mounted on the mounting substrate 110, and a first molding member 300 on the mounting substrate 110 to expose an upper surface of the first semiconductor chip 200 and first conductive connection members 220 penetrating through the first molding member 300.

The EMI shield member 400 may be disposed on the first package and may include a graphite layer 410 that is provided on the first molding member 300 to cover the first semiconductor chip 200.

The second package may include a substrate 150 stacked on the EMI shield member 400, a second semiconductor chip 250 mounted on the substrate 150, and a second molding member 350 covering the second semiconductor chip 250 on the substrate 150.

The first semiconductor chip 200 may be arranged in a chip-mounting region of the mounting substrate 110 and may be electrically connected to the mounting substrate 110 by bumps 210 on a plurality of first bonding pads 122.

The first molding member 300 may be formed on an upper surface of the mounting substrate 100 to cover the first semiconductor chip 200. The first molding member 300 may be formed to expose an upper surface of the first semiconductor chip 200.

The EMI shield member 400 may be disposed on the entire upper surface of the first molding member 300 to cover the first semiconductor chip 200 and may make contact with the upper surface of the first semiconductor chip 200 exposed by the first molding member 300. Alternatively, the EMI shield member 400 may cover only the exposed upper surface of the first semiconductor chip 200. The EMI shield member 400 may have an area corresponding to the upper surface of the first semiconductor chip 200, for example.

The EMI shield member 400 may include the graphite layer 410 covering the first semiconductor chip 200, and first and second adhesive layers 420a and 420b on upper and lower surfaces of the graphite layer 410. The first and second adhesive layers may include a non-conductive adhesive or conductive adhesive. The substrate 150 of the second package may be adhered to the upper surface of the first semiconductor chip 200 by the first and second adhesive layers 420a and 420b.

The first conductive connection member 220 may protrude from the first molding member 300 by a predetermined distance, for example. The EMI shield member 400 may expose end portions of the first conductive connection members 220 protruding from the first molding member 300.

The substrate 150 may be stacked on the first package by the exposed first conductive connection members 220. The end portions of the first conductive connection members 220 may be in contact with and electrically connected to redistribution connection pads 170 on a lower surface of the substrate 150. Accordingly, the substrate 150 of the second package may be electrically connected to the first conductive connection members 220.

The second semiconductor chip 250 may be adhered to the substrate 150 by an adhesive layer. Chip pads 256 may be formed on an upper surface of the second semiconductor chip 250. Bonding wires 254 may be drawn from the bonding pads 164 of the substrate 150 to be connected to the chip pads 256 of the second semiconductor chip 250.

Alternatively, the second semiconductor chip 250 may be mounted on the substrate 150 by solder bumps. The second semiconductor chip 250 may be mounted on the substrate 150 by various mounting methods. Additionally, the number of the stacked first and second semiconductor chips may not be limited thereto. Further, the first and second semiconductor chips may be different chips for performing different functions.

In this exemplary embodiment in accordance with principles of inventive concepts, the semiconductor package 109 may be a package on package (POP). The EMI shield member 400 including the graphite layer 410 may be interposed between the first package and the second package. The EMI shield member 400 may reduce and block electromagnetic field between the first and second packages, for example.

Although it is not illustrated in the figures, second conductive connection members may be provided to penetrate the second molding member 350, and a second EMI shield member may be provided to cover the second semiconductor chip 250. The second conductive connection members may be arranged on ground connection pads of the substrate 150, and the second EMI shield member may make contact with the second conductive connection members on the ground connection pads of the substrate 150 to be electrically connected to the second conductive connection members. Accordingly, the second EMI shield member may be electrically connected to outer connection members 140 on outer connection pads 130 of the mounting substrate 110 by the first conductive connection members 220 and the second conductive connection members.

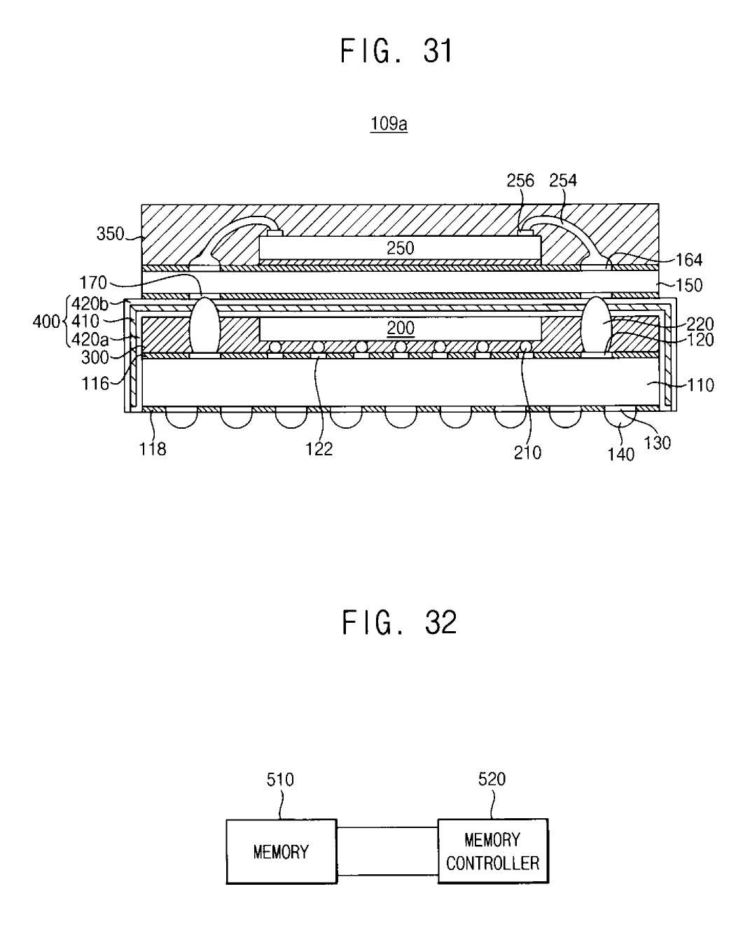

FIG. 31 is a cross-sectional view illustrating an exemplary embodiment of a semiconductor package 109a in accordance with principles of inventive concepts. The semiconductor package 109a may be substantially the same as or similar to that of FIG. 29, except for the EMI shield member. Thus, like reference numerals refer to like elements, and, for brevity and clarity, detailed descriptions of those elements will not be repeated herein.

Referring to FIG. 31, a semiconductor package 109a may include a first package, a second package mounted on the first package, and an EMI shield member 400 interposed between the first package and the second package.

In this embodiment, the EMI shield member 400 may cover at least a portion of an outer side surface of a mounting substrate 110 of the first package. Accordingly, a graphite layer 410 of the EMI shield member 400 may cover an upper surface and side surfaces of the lower package, to thereby improve EMI shielding and heat dissipation, in a manner that reduces the total thickness of the semiconductor package relative to alternative approaches.

FIG. 32 illustrates an exemplary embodiment of an electronic system that may employ a semiconductor package in accordance with principles of inventive concepts. This exemplary embodiment includes a memory 510 connected to a memory controller 520. The memory 510 may include a memory device employing a package in accordance with principles of inventive concepts such as discussed above. The memory controller 520 supplies input signals for controlling operation of the memory.

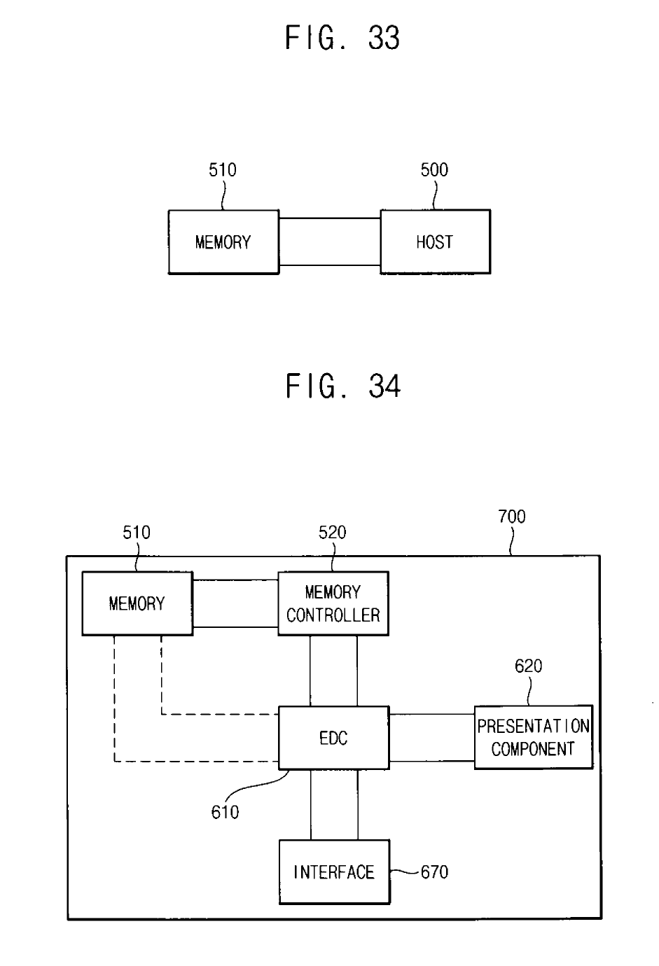

FIG. 33 illustrates an exemplary embodiment of an electronic system that may employ a semiconductor package in accordance with principles of inventive concepts. In this exemplary embodiment, a memory 510 is connected with a host system 500 and the memory 510 may include a memory device employing a package in accordance with principles of inventive concepts such as discussed above.

The host system 500 may include an electric product such as a personal computer, digital camera, mobile application, game machine, cellular telephone, tablet computer, or communication equipment, for example. The host system 500 supplies the input signals for controlling operation of the memory 510. The memory 510 is used as a data storage medium.

FIG. 34 illustrates an exemplary embodiment of an electronic system in accordance with principles of inventive concepts. This exemplary embodiment represents a portable device 700. The portable device 700 may be an MP3 player, video player, cellular telephone, personal digital assistant, tablet computer, or a combination video and audio player, for example. The portable device 700 may include the memory 510 and memory controller 520. The memory 510 may include a memory device employing a package in accordance with principles of inventive concepts such as discussed above. The portable device 700 may also includes an encoder/decoder EDC 610, a presentation component 620 and an interface 670. Data (video, audio, etc.) is inputted/outputted to/from the memory 510 by the memory controller 520 by the EDC 610.

The foregoing is illustrative of exemplary embodiments in accordance with principles of inventive concepts and is not to be construed as limiting thereof. Although exemplary embodiments in accordance with principles of inventive concepts have been described, those skilled in the art will readily appreciate that many modifications are possible in exemplary embodiments in accordance with principles of inventive concepts without materially departing from the novel teachings and advantages of inventive concepts. Accordingly, all such modifications are intended to be included within the scope of exemplary embodiments in accordance with principles of inventive concepts as defined in the claims.

1. A semiconductor package, comprising:
a mounting substrate having a chip-mounting region and a peripheral region;
a first semiconductor chip mounted on the chip-mounting region of the mounting substrate;
a first molding member on the mounting substrate to cover at least a portion of the first semiconductor chip;
a plurality of first conductive connection members penetrating at least a portion of the first molding member, the first conductive connection members electrically connected to a plurality of ground connection pads provided on the peripheral region of the mounting substrate, respectively; and
an electromagnetic interference (EMI) shield member including a graphite layer covering the first semiconductor chip and electrically connected to the first conductive connection members.

2. The semiconductor package of claim 1, wherein the first molding member leaves exposed an upper surface of the first semiconductor chip.

3. The semiconductor package of claim 2, wherein the EMI shield member makes electrical contact with the exposed upper surface of the first semiconductor chip.

4. The semiconductor package of claim 2, wherein the first semiconductor chip is electrically connected to the mounting substrate by a plurality of bumps.

5. The semiconductor package of claim 1, wherein the EMI shield member makes electrical contact with the first conductive connection members.

6. The semiconductor package of claim 1, wherein the first conductive connection member includes a solder ball disposed on the ground connection pad, and an end portion of the solder ball is exposed by the first molding member.

7. The semiconductor package of claim 1, wherein the first conductive connection member comprises a conductive material, through-holes are formed in the first molding member to expose the ground connection pads, and the conductive material fills the through-holes.

8. The semiconductor package of claim 1, wherein the EMI shield member further comprises:
a support layer supporting the graphite layer; and
a conductive adhesive layer on the graphite layer.

9. The semiconductor package of claim 1, wherein the EMI shield member covers at least a portion of an outer side surface of the mounting substrate.

10. The semiconductor package of claim 1, further comprising a second semiconductor chip stacked on the first semiconductor chip, and wherein the second semiconductor chip is electrically connected to the first semiconductor chip by a plurality of through-electrodes that penetrate the first semiconductor chip.

11. The semiconductor package of claim 1, further comprising:
a redistribution wiring substrate stacked on the first molding member and electrically connected to the first conductive connection members;
a second semiconductor chip mounted on a chip-mounting region of the redistribution wiring substrate;
a second molding member on the redistribution wiring substrate to cover at least of a portion of the second semiconductor chip; and
a plurality of second conductive connection members penetrating at least a portion of the second molding member, the second conductive connection members electrically connected to a plurality of ground connection pads provided on a peripheral region of the redistribution substrate, respectively.

12. The semiconductor package of claim 11, wherein the second molding member exposes an upper surface of the second semiconductor chip.

13. The semiconductor package of claim 12, wherein the EMI shield member makes electrical contact with the exposed upper surface of the second semiconductor chip.

14. The semiconductor package of claim 11, wherein the EMI shield member makes electrical contact with the first conductive connection members.

15. A semiconductor package, comprising:
a mounting substrate;
a first semiconductor chip mounted on the mounting substrate;
a first molding member on the mounting substrate that leaves exposed an upper surface of the first semiconductor chip; and
an electromagnetic interference (EMI) shield member including a graphite layer on the first molding member and covering the first semiconductor chip.

16. The semiconductor package of claim 15, wherein the EMI shield member makes electrical contact with the exposed upper surface of the first semiconductor chip.

17. The semiconductor package of claim 15, wherein the EMI shield member further comprises:
a support layer supporting the graphite layer; and
a conductive adhesive layer on the graphite layer.

18. The semiconductor package of claim 15, further comprising a heat dissipation plate on the EMI shield member.

19. The semiconductor package of claim 18, wherein the EMI shield member further comprises first and second adhesive layers on upper and lower surfaces of the graphite layer.

20. The semiconductor package of claim 15, further comprising a plurality of first conductive connection members penetrating at least a portion of the first molding member, the first conductive connection members electrically connected to a plurality of ground connection pads provided on a peripheral region of the mounting substrate, respectively,
and wherein the graphite layer of the EMI shield member is electrically connected to the first conductive connection members.

21-33. (canceled)

34. An electronic memory, comprising:
a mounting substrate having a chip-mounting region and a peripheral region;
a first semiconductor memory chip mounted on the chip-mounting region of the mounting substrate;
a first molding member on the mounting substrate to cover a portion of the first semiconductor memory chip, leaving the upper surface exposed;
a plurality of first conductive connection members penetrating at least a portion of the first molding member, the first conductive connection members electrically connected to a plurality of ground connection pads provided on the peripheral region of the mounting substrate, respectively;
a second semiconductor memory chip stacked on the first semiconductor memory chip, wherein the second semiconductor memory chip is electrically connected to the first semiconductor memory chip by a plurality of through-electrodes that penetrate the first semiconductor memory chip; and
an electromagnetic interference (EMI) shield member including a graphite layer covering the first semiconductor memory chip, electrically connected to the first conductive connection members and in contact with the exposed upper surface of the first semiconductor memory chip.

35. The semiconductor memory of claim 34, wherein the first semiconductor memory chip is electrically connected to the mounting substrate by a plurality of bumps.

36. The semiconductor memory of claim 34, wherein the EMI shield member makes electrical contact with the first conductive connection members.

37. The semiconductor memory of claim 34, wherein the first conductive connection member includes a solder ball disposed on the ground connection pad, and an end portion of the solder ball is exposed by the first molding member.

38. The semiconductor memory of claim 34, wherein the first conductive connection member comprises a conductive material, through-holes are formed in the first molding member to expose the ground connection pads, and the conductive material fills the through-holes.

39. The semiconductor memory of claim 34, wherein the EMI shield member further comprises:
a support layer supporting the graphite layer; and
a conductive adhesive layer on the graphite layer, wherein the EMI shield member covers at least a portion of an outer surface of the mounting substrate.

40. The semiconductor memory of claim 34, further comprising:
a redistribution wiring substrate stacked on the first molding member and electrically connected to the first conductive connection members;
wherein the second semiconductor memory chip is mounted on a chip-mounting region of the redistribution wiring substrate;
a second molding member on the redistribution wiring substrate to cover a portion of the second semiconductor chip, leaving exposed an upper surface of the second semiconductor memory chip; and
a plurality of second conductive connection members penetrating at least a portion of the second molding member, the second conductive connection members electrically connected to a plurality of ground connection pads provided on a peripheral region of the redistribution substrate, respectively.

41. The semiconductor memory of claim 40, wherein the EMI shield member makes electrical contact with the exposed upper surface of the second semiconductor chip.

42. An electronic memory system including the semiconductor memory of claim 34.

43. An electronic system including the electronic memory system of claim 42.

44. A portable electronic device including the semiconductor memory of claim 34.

45. A wireless electronic device including the memory of claim 34.
